(19) United States
(12) Patent Application Publication
(10) Pub. No.: US 2012/0319136 A1
(43) Pub. Date: Dec. 20, 2012

(54) SILICON CARBIDE SEMICONDUCTOR DEVICE AND METHOD FOR MANUFACTURING THE SAME

(75) Inventors: Masato Noborio, Kariya-city (JP); Kensaku Yamamoto, Chiryu-city (JP); Hideo Matsuki, Obu-city (JP); Hidefumi Takaya, Toyota-city (JP); Masahiro Sugimoto, Toyota-city (JP); Narumasa Soejima, Seto-city (JP); Tsuyoshi Ishikawa, Nisshin-city (JP); Yukihiko Watanabe, Nagoya-city (JP)

(73) Assignees: TOYOTA JIDOSHA KABUSHIKI KAISHA, Toyota-shi, Aichi-ken (JP); DENSO CORPORATION, Kariya-city, Aichi-pref. (JP)

(21) Appl. No.: 13/581,497

(22) PCT Filed: Feb. 6, 2012
(86) PCT No.: PCT/JP2012/000770

§ 371 Date: Aug. 28, 2012

(30) Foreign Application Priority Data
Feb. 11, 2011 (JP) 2011-027997

(51) Int. Cl. H01L 29/24; H01L 21/336

(52) U.S. Cl. 257/77; 438/270; 257/E29.104; 257/E21.41

(57) ABSTRACT

A SiC device includes an inversion type MOSFET having: a substrate, a drift layer, and a base region stacked in this order; source and contact regions in upper portions of the base region; a trench penetrating the source and base regions; a gate electrode on a gate insulating film in the trench; a source electrode coupled with the source and base region; a drain electrode on a back of the substrate; and multiple deep layers in an upper portion of the drift layer deeper than the trench. Each deep layer has an impurity concentration distribution in a depth direction, and an inversion layer is provided in a portion of the deep layer on the side of the trench under application of the gate voltage.

### CROSS REFERENCE TO RELATED APPLICATION

This application is based on Japanese Patent Application No. 2011-27997 filed on Feb. 11, 2011, the disclosure of which is incorporated herein by reference.

### TECHNICAL FIELD

The present disclosure relates to a silicon carbide semiconductor device having a trench gate type MOSFET and a method for manufacturing a silicon carbide semi-conductor device having a trench gate type MOSFET,

### BACKGROUND ART

SiC semiconductor devices, an increase in channel density is effective for providing a greater electric current. A MOSFET with a trench gate structure has therefore been adopted and already been put to practical use in silicon transistors. Needless to say, this trench gate structure can be applied to a SiC semiconductor device. A serious problem however occurs when it is applied to SiC. Described specifically, SiC has breakdown field strength ten times that of silicon so that a SiC semiconductor device is used while applying a voltage about ten times that of a silicon device. As a result, an electric field ten times that of the silicon device is applied to a gate insulating film formed in a trench in SiC and the gate insulating film is easily broken at a corner of the trench.

In order to overcome this problem, Patent Document 1 proposes a SiC semiconductor device having, below a p type base region, p-type deep layers which are formed in a stripe pattern and cross a trench constituting a trench gate structure. In this SiC semi-conductor device, by extending a depletion layer from each of p type deep layers toward an n-type drift layer to prevent application of a high voltage to a gate insulating film, an electric field concentration in the gate insulating film can be mitigated and thereby the gate insulating film can be prevented from being broken.

Although the structure equipped with the p type deep layers as described in Patent Document 1 is effective for preventing an electric field concentration to the gate insulating film, a current path is narrowed by the p type deep layers and a JFET region is formed between two p type deep layers adjacent to each other, resulting in an increase in on-resistance.

### CITATION LIST

### Patent Literature

PTL 1: Japanese Patent Laid-Open No. 2009-191065

### SUMMARY

In view of the above-described problem, it is an object of the present disclosure to provide a silicon carbide semiconductor device having a trench gate type MOSFET with a low on-state resistance. It is another object of the present disclosure to provide a method for manufacturing a silicon carbide semiconductor device having a trench gate type MOSFET with a low on-state resistance.

According to a first aspect of the present disclosure, a silicon carbide semiconductor device includes: an inversion type MOSFET with a trench gate structure. The inversion type MOSFET includes: a substrate having first or second conductivity type and made of silicon carbide; a drift layer disposed on the substrate, having an impurity concentration lower than the substrate, having the first conductivity type, and made of silicon carbide; a base region disposed on the drift layer, having the second conductivity type, and made of silicon carbide; a source region disposed in an upper portion of the base region, having an impurity concentration higher than the drift layer, having the first conductivity type, and made of silicon carbide; a contact region disposed in another upper portion of the base region, having an impurity concentration higher than the base layer, having the second conductivity type, and made of silicon carbide; a trench extending from a surface of the source region to penetrate the base region, and having a first direction as a longitudinal direction; a gate insulating film disposed on an inner wall of the trench; a gate electrode disposed on the gate insulating film in the trench; a source electrode electrically coupled with the source region and electrically coupled with the base region via the contact region; and a drain electrode disposed on a back side of the substrate. The inversion type MOSFET is configured to flow current between the source electrode and the drain electrode via the source region, an inversion type channel region and the drift layer. The inversion type channel region is provided in a portion of the base region positioned on a side of the trench by controlling a gate voltage applied to the gate electrode. The inversion type MOSFET further includes: a plurality of deep layers having the second conductivity type. Each deep layer is disposed in an upper portion of the drift layer below the base region, has a depth deeper than the trench, and extends along a second direction, which crosses the first direction. Each deep layer has an impurity concentration distribution in a depth direction of the deep layer. When the gate voltage is applied to the gate electrode, an inversion layer is provided in a portion of the deep layer positioned on the side of the trench.

In the above device, since the current flowing through the channel flows not only the channel but also the inversion layer formed in the portion of the deep layer. Thus, a JFET region between the deep layers has a low JFET resistance, so that an on-state resistance is reduced.

According to a second aspect of the present disclosure, a method of manufacturing a silicon carbide semiconductor device includes: forming a drift layer on a substrate, wherein the substrate is made of silicon carbide and has a first or second conductivity type, and the drift layer is made of silicon carbide, has the first conductivity type, and has an impurity concentration lower than the substrate; forming a plurality of deep layers having the second conductivity type in a surface portion of the drift layer by implanting an ion on a surface of the drift layer through a first mask after the first mask is formed on the surface of the drift layer; forming a base region having the second conductivity type and made of silicon carbide on the deep layers and the drift layer; forming a source region in a surface portion of the base region by implanting a first conductivity type impurity on a surface of the base region, wherein the source region has an impurity concentration higher than the drift layer, having the first conductivity type, and made of silicon carbide; forming a contact region in another surface portion of the base region by implanting a second conductivity type impurity on the surface of the base region, wherein the contact region has an impurity concentration higher than the base region, having the second conductivity type, and made of silicon carbide; forming a trench on a surface of the source region to penetrate the base region and to reach the drift layer, wherein the trench is shallower than each deep layer, and has a first direction as a longitudinal direction; forming a gate insulating film on an inner wall of the trench; forming a gate electrode on the gate insulating film in the trench; forming a source electrode to be electrically coupled with the source region and to be coupled with the base region via the contact region; and forming a drain electrode on a back side of the substrate. Each deep layer is disposed in an upper portion of the drift layer below the base region, has a depth deeper than the trench, and extends along a second direction, which crosses the first direction. Each deep layer has an impurity concentration distribution in a depth direction of the deep layer. When the gate voltage is applied to the gate electrode, an inversion layer is provided in a portion of the deep layer positioned on the side of the trench.

In the above method, since the current flowing through the channel flows not only the channel but also the inversion layer formed in the portion of the deep layer. Thus, a JFET region between the deep layers has a low JFET resistance, so that an on-state resistance is reduced,

According to a third aspect of the present disclosure, a method of manufacturing a silicon carbide semiconductor device includes: forming a drift layer on a substrate, wherein the substrate is made of silicon carbide and has a first or second conductivity type, and the drift layer is made of silicon carbide, has the first conductivity type, and has an impurity concentration lower than the substrate; forming a second conductivity type film on a surface of the drift layer by an epitaxial growth method; implanting an ion on a surface of the second conductivity type film through a first mask after the first mask is formed on the surface of the second conductivity type film so that the second conductivity type film is divided into a plurality of parts, each of which provide a corresponding deep layer, and an implanted part of the second conductivity type film between a plurality of deep layers provides the drift layer; forming a base region having the second conductivity type and made of silicon carbide on the deep layers and the drift layer; forming a source region in a surface portion of the base region by implanting a first conductivity type impurity on a surface of the base region, wherein the source region has an impurity concentration higher than the drift layer, having the first conductivity type, and made of silicon carbide; forming a contact region in another surface portion of the base region by implanting a second conductivity type impurity on the surface of the base region, wherein the contact region has an impurity concentration higher than the base region, having the second conductivity type, and made of silicon carbide; forming a trench on a surface of the source region to penetrate the base region and to reach the drift layer, wherein the trench is shallower than each deep layer, and has a first direction as a longitudinal direction; forming a gate insulating film on an inner wall of the trench; forming a gate electrode on the gate insulating film in the trench; forming a source electrode to be electrically coupled with the source region and to be coupled with the base region via the contact region; and forming a drain electrode on a back side of the substrate. Each deep layer is disposed in an upper portion of the drift layer below the base region, has a depth deeper than the trench, and extends along a second direction, which crosses the first direction. Each deep layer has an impurity concentration distribution in a depth direction of the deep layer. When the gate voltage is applied to the gate electrode, an inversion layer is provided in a portion of the deep layer positioned on the side of the trench.

In the above method, since the current flowing through the channel flows not only the channel but also the inversion layer formed in the portion of the deep layer. Thus, a JFET region between the deep layers has a low JFET resistance, so that an on-state resistance is reduced.

### BRIEF DESCRIPTION OF DRAWINGS

The above and other objects, features and advantages of the present disclosure will become more apparent from the following detailed description made with reference to the accompanying drawings. In the drawings:

FIG. 1 is a perspective cross-sectional view of a MOSFET having an inversion type trench gate structure according to a first embodiment;

FIG. 2A is a cross-sectional view taken along the line IIA-IIA of FIG. 1;

FIG. 2B is a cross-sectional view taken along the line IIB-IIB of FIG. 1;

FIG. 2C is a cross-sectional view taken along the line IIC-IIC of FIG. 1;

FIG. 2D is a cross-sectional view taken along the line IID-IID of FIG. 1;

FIG. 3 is a partial perspective cross-sectional view of the vicinity of a trench in a trench gate structure shown while omitting therefrom a gate oxide film, a gate electrode, and the like;

FIG. 4A is a cross-sectional view of the MOSFET taken along line IIB-IIB in FIG. 1 showing a manufacturing step of the MOSFET having a trench gate structure shown in FIG. 1;

FIG. 4B is a cross-sectional view of the MOSFET taken along line IID-IID in FIG. 1 showing a manufacturing step of the MOSFET having a trench gate structure shown in FIG. 1;

FIG. 4C is a cross-sectional view of the MOSFET taken along line IIB-IIB in FIG. 1 showing a manufacturing step of the MOSFET having a trench gate structure shown in FIG. 1;

FIG. 4D is a cross-sectional view of the MOSFET taken along line in FIG. 1 showing a manufacturing step of the MOSFET having a trench gate structure shown in FIG. 1;

FIG. 4E is a cross-sectional view of the MOSFET taken along line IIB-IIB in FIG. 1 showing a manufacturing step of the MOSFET having a trench gate structure shown in FIG. 1;

FIG. 4F is a cross-sectional view of the MOSFET taken along line IID-IID in FIG. 1 showing a manufacturing step of the MOSFET having a trench gate structure shown in FIG. 1;

FIG. 5A is a cross-sectional view of the MOSFET taken along line IIB-IIB in FIG. 1 showing a manufacturing step of the MOSFET having a trench gate structure following those of FIGS. 4A, 4C and 4E;

FIG. 5B is a cross-sectional view of the MOSFET taken along line IID-IID in FIG. 1 showing a manufacturing step of the MOSFET having a trench gate structure following those of FIGS. 4B, 4D and 4F;

FIG. 5C is a cross-sectional view of the MOSFET taken along line IIB-IIB in FIG. 1 showing a manufacturing step of the MOSFET having a trench gate structure following those of FIGS. 4A, 4C and 4E;

FIG. 5D is a cross-sectional view of the MOSFET taken along line IID-IID in FIG. 1 showing a manufacturing step of the MOSFET having a trench gate structure following those of FIGS. 4B, 4D and 4F;

FIG. 5E is a cross-sectional view of the MOSFET taken along line IIB-IIB in FIG. 1 showing a manufacturing step of the MOSFET having a trench gate structure following those of FIGS. 4A, 4C and 4E;

FIG. 5F is a cross-sectional view of the MOSFET taken along line IID-IID in FIG. 1 showing a manufacturing step of the MOSFET having a trench gate structure following those of FIGS. 4B, 4D and 4F;

FIG. 6 is a perspective cross-sectional view of a SiC semiconductor device according to a second embodiment;

FIG. 7A is a cross-sectional view taken along the line VIIA-VIIA in parallel with the xz plane in FIG. 6;

FIG. 7B is a cross-sectional view taken along the line VIIB-VIIB in parallel with the yz plane in FIG. 6;

FIG. 8 is a perspective cross-sectional view of a SiC semiconductor device according to a third embodiment;

FIG. 9A is a cross-sectional view taken along the line IXA-IXA in parallel with the xz plane in FIG. 8;

FIG. 9B is a cross-sectional view taken along the line IXB-IXB in parallel with the yz plane in FIG. 8;

FIG. 10 is a perspective cross-sectional view of a SiC semiconductor device according to a fourth embodiment;

FIG. 11A is a cross-sectional view taken along the line XIA-XIA in parallel with the xz plane in FIG. 10;

FIG. 11B is a cross-sectional view taken along the line XIB-XIB in parallel with the yz plane in FIG. 10;

FIG. 12 is a perspective cross-sectional view of a SiC semiconductor device according to a fifth embodiment;

FIG. 13A is a cross-sectional view taken along the line XIIIA-XIIIA in parallel with the xz plane in FIG. 12;

FIG. 13B is a cross-sectional view taken along the line XIIIB-XIIIB in parallel with the yz, plane in FIG. 12;

FIG. 14 is a perspective cross-sectional view of a SiC semiconductor device according to a sixth embodiment;

FIG. 15A is a cross-sectional view taken along the line XVA-XVA in parallel with the xz plane in FIG. 14;

FIG. 15B is a cross-sectional view taken along the line XVB-XVB i parallel with the yz plane in FIG. 14;

FIG. 16 is a perspective cross-sectional view of a SiC semiconductor device according to a seventh embodiment;

FIG. 17A is a cross-sectional view taken along the line XVIIA-XVIIA in parallel with the xz plane in FIG. 16;

FIG. 17B is a cross-sectional view taken along the line XVIIB-XVIIB in

FIG. 18A is a cross-sectional view of the MOSFET taken along line XVIIA-XVIIA in FIG. 16 showing a manufacturing step of the MOSFET having a trench gate structure shown in FIG. 16;

FIG. 18B is a cross-sectional view of the MOSFET taken along line XVIIB-XVIIB in FIG. 16 showing a manufacturing step of the MOSFET having a trench gate structure shown in FIG. 16;

FIG. 18C is a cross-sectional view of the MOSFET taken along line XVIIA-XVIIA in FIG. 16 showing a manufacturing step of the MOSFET having a trench gate structure shown in FIG. 16;

FIG. 18D is a cross-sectional view of the MOSFET taken along line XVIIB-XVIIB in FIG. 16 showing a manufacturing step of the MOSFET having a trench gate structure shown in FIG. 16;

FIG. 18E is a cross-sectional view of the MOSFET taken along line XVIIA-XVIIA in FIG. 16 showing a manufacturing step of the MOSFET having a trench gate structure shown in FIG. 16;

FIG. 18F is a cross-sectional view of the MOSFET taken along line XVIIB-XVIIB in FIG. 16 showing a manufacturing step of the MOSFET having a trench gate structure shown in FIG. 16;

FIG. 19A is a cross-sectional view of the MOSFET taken along line XVIIA XVIIA in FIG. 16 showing a manufacturing step of the MOSFET having a trench gate structure following those of FIGS. 18A, 18C and 18E;

FIG. 19B is a cross-sectional view of the MOSFET taken along line XVIIB-XVIIB in FIG. 16 showing a manufacturing step of the MOSFET having a trench gate structure following those of FIGS. 18B, 18D and 18F;

FIG. 19C is a cross-sectional view of the MOSFET taken along line XVIIA-XVIIA in FIG. 16 showing a manufacturing step of the MOSFET having a trench gate structure following those of FIGS. 18A, 18C and 18E;

FIG. 19D is a cross-sectional views of the MOSFET taken along line XVIIB-XVIIB in FIG. 16 showing a manufacturing step of the MOSFET having a trench gate structure following those of FIGS. 18B, 18D and 18F;

FIG. 19E is a cross-sectional views of the MOSFET taken along line XVIIA-XVIIA in FIG. 16 showing a manufacturing step of the MOSFET having a trench gate structure following those of FIGS. 18A, 18C and 18E;

FIG. 19F is a cross-sectional view of the MOSFET taken along line XVIIB-XVIIB in FIG. 16 showing a manufacturing step of the MOSFET having a trench gate structure following those of FIGS. 18B, 18D and 18F;

FIG. 20 is a perspective cross-sectional view of a SiC semiconductor device according to an eighth embodiment;

FIG. 21A is a cross-sectional view taken along the line XXIA-XXIA parallel with the xz plane in FIG. 20;

FIG. 21B is a cross-sectional view taken along the line XXIB-XXIB in parallel with the yz plane in FIG. 20;

FIG. 22A is a cross-sectional view of the MOSFET taken along line IIB-IIB in FIG. 1 showing a manufacturing step of the MOSFET having a trench gate structure shown in FIG. 1, according to a ninth embodiment;

FIG. 22B is a cross-sectional view of the MOSFET taken along line IID-IID in FIG. 1 showing a manufacturing step of the MOSFET having a trench gate structure shown in FIG. 1 according to the ninth embodiment;

FIG. 22C is a cross-sectional view of the MOSFET taken along line IIB-IIB in FIG. 1 showing a manufacturing step of the MOSFET having a trench gate structure shown in FIG. 1, according to a ninth embodiment;

FIG. 22D is a cross-sectional view of the MOSFET taken along line IID-IID in FIG. 1 showing a manufacturing step of the MOSFET having a trench gate structure shown in FIG. 1 according to the ninth embodiment;

FIG. 22E is a cross-sectional view of the MOSFET taken along line IIB-IIB in FIG. 1 showing a manufacturing step of the MOSFET having a trench gate structure shown in FIG. 1, according to a ninth embodiment;

FIG. 22F is a cross-sectional view of the MOSFET taken along line IID-IID in FIG. 1 showing a manufacturing step of the MOSFET having a trench gate structure shown in FIG. 1 according to the ninth embodiment;

FIG. 23A is a cross-sectional view of the MOSFET taken along line IIB-IIB in FIG. 1 showing a manufacturing step of the MOSFET having a trench gate structure following those of FIGS. 22A, 22C and 22E;

FIG. 23B is a cross-sectional view of the MOSFET taken along line IID-IID in FIG. 1 showing a manufacturing step of the MOSFET having a trench gate structure following those of FIGS. 22B, 22D and 22F;

FIG. 23C is a cross-sectional view of the MOSFET taken along line IIB-IIB in FIG. 1 showing a manufacturing step of the MOSFET having a trench gate structure following those of FIGS. 22A, 22C and 22E;

FIG. 23D is a cross-sectional view of the MOSFET taken along line IID-IID in FIG. 1 showing a manufacturing step of the MOSFET having a trench gate structure following those of FIGS. 22B, 22D and 22F;

FIG. 23E is a cross-sectional view of the MOSFET taken along line IIB-IIB in FIG. 1 showing a manufacturing step of the MOSFET having a trench gate structure following those of FIGS. 22A, 22C and 22E;

FIG. 23F is a cross-sectional view of the MOSFET taken along line IID-IID in FIG. 1 showing a manufacturing step of the MOSFET having a trench gate structure following those of FIGS. 22B, 22D and 22F;

FIG. 24A is a cross-sectional view of the MOSFET taken along line XXIA-XXIA in FIG. 20 showing a manufacturing step of the MOSFET having a trench gate structure shown in FIG. 20, according to a tenth embodiment;

FIG. 24B is a cross-sectional view of the MOSFET taken along line XXIB-XXIB in FIG. 20 showing a manufacturing step of the MOSFET having a trench gate structure shown in FIG. 20 according to the tenth embodiment;

FIG. 24C is a cross-sectional view of the MOSFET taken along line XXIA-XXIA in FIG. 20 showing a manufacturing step of the MOSFET having a trench gate structure shown in FIG. 20, according to a tenth embodiment;

FIG. 24D is a cross-sectional view of the MOSFET taken along line XXIB-XXIB in FIG. 20 showing a manufacturing step of the MOSFET having a trench gate structure shown in FIG. 20 according to the tenth embodiment;

FIG. 24E is a cross-sectional view of the MOSFET taken along line XXIA-XXIA in FIG. 20 showing a manufacturing step of the MOSFET having a trench gate structure shown in FIG. 20, according to a tenth embodiment;

FIG. 24F is a cross-sectional view of the MOSFET taken along line XXIB-XXIB in FIG. 20 showing a manufacturing step of the MOSFET having a trench gate structure shown in FIG. 20 according to the tenth embodiment;

FIG. 25A is a cross-sectional view of the MOSFET taken along line XXIA-XXIA in FIG. 20 showing a manufacturing step of the MOSFET having a trench gate structure following those of FIGS. 24A, 24C and 24E;

FIG. 25B is a cross-sectional view of the MOSFET taken along line XXIB-XXIB in FIG. 20 showing a manufacturing step of the MOSFET having a trench gate structure following those of FIGS. 24B, 24D and 24F;

FIG. 25C is a cross-sectional view of the MOSFET taken along line XXIA-XXIA in FIG. 20 showing a manufacturing step of the MOSFET having a trench gate structure following those of FIGS. 24A, 24C and 24E;

FIG. 25D is a cross-sectional view of the MOSFET taken along line XXIB-XXIB in FIG. 20 showing a manufacturing step of the MOSFET having a trench gate structure following those of FIGS. 24B, 24D and 24F;

FIG. 25F, is a cross-sectional view of the MOSFET taken along line XXIA-XXIA in FIG. 20 showing a manufacturing step of the MOSFET having a trench gate structure following those of FIGS. 24A, 24C and 24E; and

FIG. 25F is a cross-sectional view of the MOSFET taken along line XXIB-XXIB in FIG. 20 showing a manufacturing step of the MOSFET having a trench gate structure following those of FIGS. 24B, 24D and 24F.

### DESCRIPTION OF EMBODIMENTS

### First Embodiment

A first embodiment will next be described. Here, a MOSFET with an inversion type trench gate structure will be described as an element which a SiC semiconductor device is equipped with.

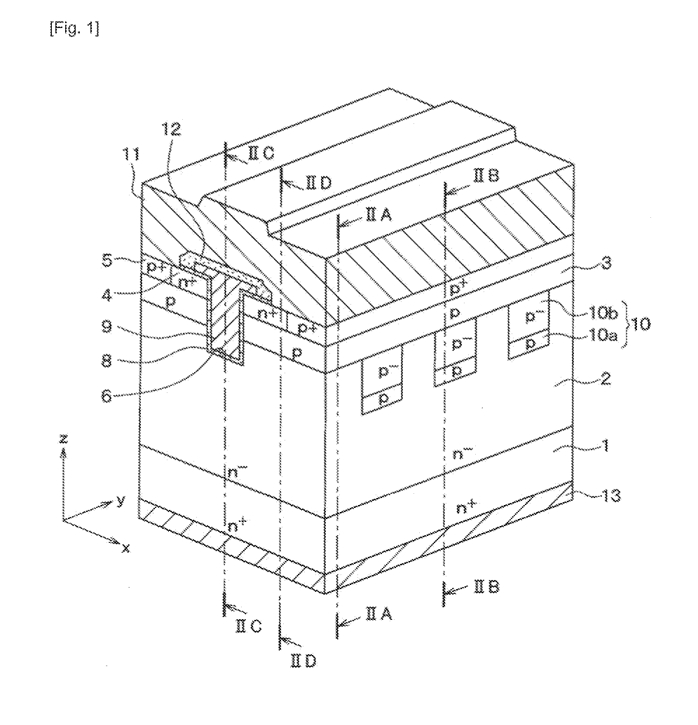

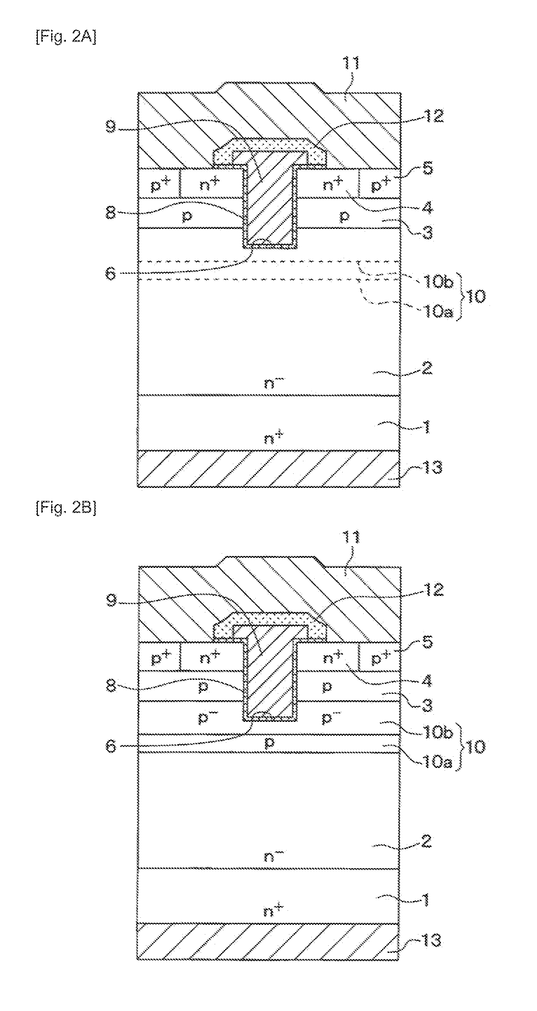

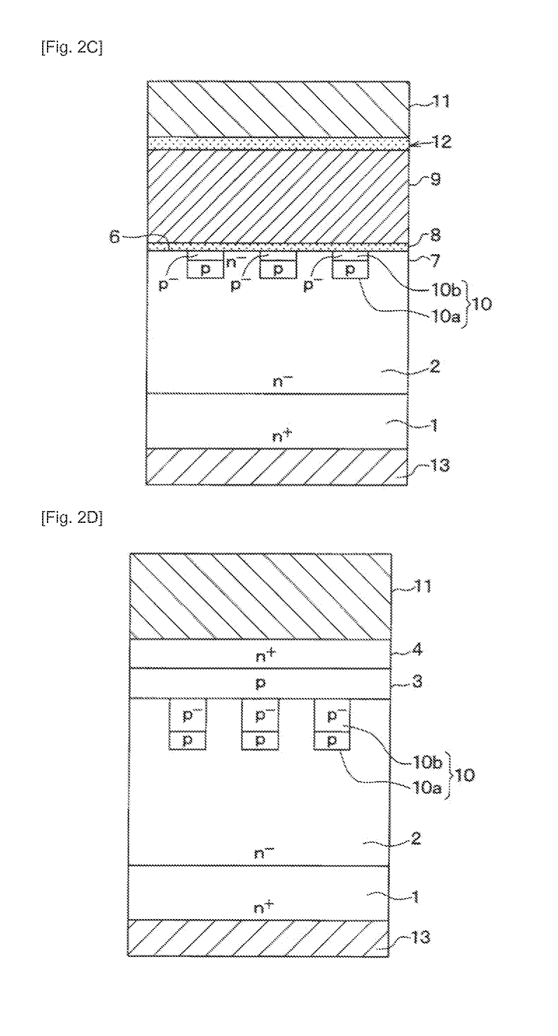

FIG. 1 is a perspective cross-sectional view of a MOSFET having a trench gate structure according to the present embodiment. This drawing corresponds to one cell of the MOSFET. Although only one cell of the MOSFET is shown in this diagram, two or more columns of MOSFETs having a similar structure to that of the MOSFET of FIG. 1 are arranged adjacent to each other. FIGS. 2A to 2D are cross-sectional views of the MOSFET of FIG. 1. FIG. 2A is a cross-sectional view of FIG. 1 taken along the line IIA-IIA in parallel with the xz plane in FIG. 1; FIG. 2B is a cross-sectional view taken along the line IIB-IIB in parallel with the xz, plane in FIG. 1, FIG. 2C is a cross-sectional view of FIG. 1 taken along the line IIC-IIC in parallel with the yz plane in FIG. 1, and FIG. 2D is a cross-sectional view taken along the line IID-IID in parallel with the yz plane in FIG. 1.

In MOSFET shown in FIG. 1 and FIGS. 2A to 2D, an n⁺ type substrate 1 made of SiC is used as a semiconductor substrate. The n⁺ type substrate 1 has, for example, a concentration of n type impurities, such as phosphorus, of 1.0×10¹⁹/cm³ and a thickness of about 300 micrometer. This n⁺ type substrate 1 has, in the surface thereof, an n⁻ type drift layer 2 having, for example, a concentration of n type impurities, such as phosphorus, of from 3.0×10¹⁵/cm³ to 7.0×10¹⁵/cm³ and a thickness of from about 10 to 15 micrometer and made of SiC. The impurity concentration of this n⁻ type drift layer 2 may be uniform in the depth direction, but preferably has a gradient concentration distribution in which the concentration of a portion of the n⁻ type drift layer 2 on the side of the n⁺ type substrate 1 is higher than that of a portion of the n⁻ type drift layer 2 on the side distant from the type substrate 1. For example, it is recommended to make the impurity concentration of a portion of the n⁻ type drift layer 2 within a range from the surface of the n⁺ type substrate 1 to about 3 to 5 micrometer therefrom higher by about 2.0×10¹⁵/cm³ than another portion. This makes it possible to reduce the internal resistance of the n⁻ type drift layer 2, thereby achieving a reduction in on-resistance.

This n⁻ type drift layer 2 has, on the surface layer portion thereof, a p type base region 3 and the p type base region 3 has, on the upper layer portion thereof, an n⁺ type source region 4 and p⁺ type contact layer 5.

The p type base region 3 has, for example, a concentration of p type impurities, such as boron or aluminum, of 5.0×10¹⁶ to 2.0×10¹⁹/cm³ and a thickness of about 2.0 Micrometer. The n⁺ type source region 4 has, in the surface layer thereof, for example, a concentration of n type impurities (surface concentration) such as phosphorus of 1.0×10²¹/cm² and a thickness of about 0.3 micrometer. The p⁺ type contact layer 5 has, in the surface layer thereof, for example, a concentration of p type impurities (surface concentration) such as boron or aluminum of 1.0×10²¹/cm² and a thickness of about 0.3 micrometer. The n⁺ type source region 4 is placed on both sides of a trench gate structure which will be described later and the p⁺ type contact layer 5 is provided on the side opposite to the trench gate structure with the n⁺ type source region 4 therebetween.

A trench 6 having, for example, a width of from 1.4 to 2.0 micrometer and a depth of 2.0 micrometer or greater (for example, 2.4 micrometer) penetrates through the p type base region 3 and the n⁺ type source region 4 and it reaches the n⁻ type drift layer 2. The p type base region 3 and the n⁺ type source region 4 are placed so as to be in contact the side surface of the trench 6.

The inner wall surface of the trench 6 is covered with a gate oxide film 8 and the trench 6 is filled with a gate electrode 9 comprised of doped Poly-Si formed on the surface of the gate oxide film 8. The gate oxide film 8 is formed by thermally oxidizing the inner wall surface of the trench 6. The gate oxide film 8 has a thickness of about 100 nm both on the side surface and the bottom of the trench 6.

The trench gate structure has such a constitution. This trench gate structure extends with the y direction in FIG. 1 as a longitudinal direction. Two or more trench gate structures are arranged in parallel along the x direction of FIG. 1, thus forming a stripe pattern. The n⁺ type source region 4 and the p+type contact layer 5 also extend along the longitudinal direction of the trench gate structure.

Further, a p type deep layer 10 extending in a direction crossing the trench gate structure is formed in the n⁻ type drift layer 2 below the p type base region 3. In the present embodiment, the p type deep layer 10 extends in a normal direction (x direction in FIG. 1) relative to a portion of the side surface of the trench 6 in which a channel region is formed in the trench gate structure, that is, extends in a direction perpendicular to the longitudinal direction of the trench 6. A plurality of such p type deep layers 10 is arranged in the longitudinal direction of the trench 6. This p type deep layer 10 is located to a depth deeper than the bottom of the trench 6. Its depth from the surface of the n⁻ type drift layer 2 is, for example, from about 2.6 to 3.0 micrometer (depth from the bottom portion of the p type base region 3 is, for example, from 0.6 to 1.0 micrometer). The p type deep layer 10 is in contact with the p type base region 3 so that it is fixed to a potential equal to that of the p type base region 3.

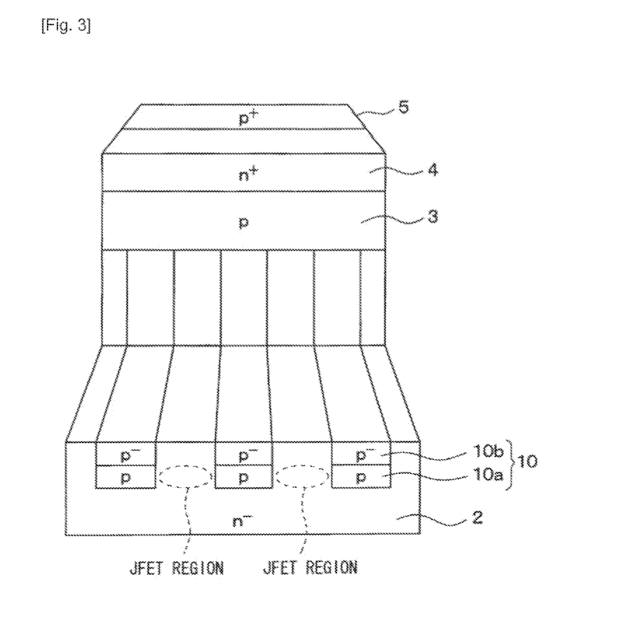

FIG. 3 is a partial perspective cross-sectional view of the vicinity of the trench 6 in the trench gate structure shown while omitting the gate oxide film 8 and the gate electrode 9 therefrom. As illustrated in FIG. 1, FIGS. 2A to 2D, and FIG. 3, the p type deep layer 10 of the present embodiment is equipped with two regions different in concentration, that is, a heavily doped region 10a and a lightly doped region 10b. In the present embodiment, the p type deep layer 10 is provided with a stepped concentration gradient in the depth direction, meaning that it has the heavily doped region 10a and the lightly doped region 10b having a lower impurity concentration than the heavily doped region. For example, in the heavily doped region 10a, in order to relax an electric field concentration in the gate oxide film 8, thereby preventing dielectric breakdown, the concentration of p type impurities such as boron or aluminum is set at, for example, from 1.0×10¹⁷/cm³ to 1.0×10¹⁹/cm³ in expectation of breakdown voltage. In the lightly doped region 10b, on the other hand, the concentration is set at, for example, from 1.0×10¹⁵/cm³ to 1.0×10¹⁷/cm³ at which an inversion layer is formed around the trench 6 when a gate voltage is applied to the gate electrode 9.

In the present embodiment, the depth of a boundary between the heavily doped region 10a and the lightly doped region 10b, in other words, the depth of the bottom surface of the lightly doped region 10b is located deeper than the trench 6 and the lightly doped region 10b is placed from the side surface to the bottom portion of the trench 6. In the present embodiment, the lightly doped region 10b positioned on the side surface and the bottom portion of the trench 6 becomes an inversion layer.

The n⁺ type source region 4, the p⁺ type contact layer 5, and the gate electrode 9 have on the surfaces thereof a source electrode 11 and gate wiring (not illustrated). The source electrode 11 and the gate wiring are each comprised of a plurality of metals (for example, Ni/Al). At least a portion of them to be brought into contact with an n type SiC (more specifically, the n⁺ type source region 4 and, when doped with n, the gate electrode 9) is comprised of a metal which can form an ohmic contact with the n type SiC and at least a portion of them to be brought into contact with a p type. SiC (more specifically, p⁺ type contact layer 5 and, when doped with p, the gate electrode 9) is comprised of a metal which can form an ohmic contact with the p type SiC. The source electrode 11 and the gate wiring are formed on an interlayer insulating film 12 and therefore they are electrically insulated. Through a contact hole formed in the interlayer insulating film 12, the source electrode 11 is in electric contact with the n⁺ type source region 4 and the p⁺ type contact layer 5 and the gate wiring is in electric contact with the gate electrode 9.

The n⁺ type substrate 1 has, on the back surface side thereof, a drain electrode 13 electrically coupled to the n⁺ type substrate 1. Such a structure constitutes MOSFET having an n channel and inversion type trench gate structure.

Such a MOSFET having an inversion type trench gate structure operates as follows.

Before a gate voltage is applied to the gate electrode 9, no inversion layer is formed in both the p type base region 3 and the p type deep layer 10. Accordingly, even if a positive voltage is applied to the drain electrode 13, electrons cannot reach the p type base region 3 from the n⁺ type source region 4 and no electric current flows between the source electrode 11 and the drain electrode 13.

In an off state (gate voltage=0 V, drain voltage=650 V, source voltage=0 V), when a voltage is applied to the drain electrode 13, it becomes a reverse bias so that a depletion layer expands from between the p type base region 3 and the n⁻ type drift layer 2. Since the impurity concentration of the p type base region 3 is higher than that of the n⁻ type drift layer 2, the depletion layer expands mostly toward the n⁻ type drift layer 2. For example, in the case where the impurity concentration of the p type base region 3 is 10 times higher than the impurity concentration of the n⁻ type drift layer 2, the depletion layer expands about 0.7 micrometer toward the p type base region 3 and about 7.0 micrometer toward the n⁻ type drift layer 2. However, the thickness of the p type base region 3 is set to 2.0 micrometer that is greater than the expanding amount of the depletion layer so that a punching through does not occur. Then, because the depletion layer expands more than the case where the drain is 0 V and a region that acts as an insulator further expands, electric current does not flow between the source electrode 11 and the drain electrode 13.

In addition, because the gate voltage is 0 V, an electric field is applied between the drain and the gate. Therefore, an electric field concentration may occur at the bottom of the gate oxide film 8. Since the p type deep layer 10 deeper than the trench 6 is provided, however, the depletion layer at a PN junction between the p type deep layer 10 and the n⁻ type drift layer 2 largely expands toward the n⁻ type drift layer 2 and a high voltage due to the influence of the drain voltage is not easily applied to the gate oxide film 8. Especially when the impurity concentration of the heavily doped region 10a of the p type deep layer 10 is set higher than that of the p type base region 3, the expanding amount of the depletion layer toward the n⁻ type drift layer 2 further increases. This makes it possible to relax an electric field concentration in the gate oxide film 8, especially, the electric field concentration in the gate oxide film 8 at the bottom of the trench 6 and thereby prevent breakage of the gate oxide film 8.

On the other hand, in an on state (gate voltage=20 V, drain voltage=1 V, and source voltage=0 V), a gate voltage of 20 V is applied to the gate electrode 9 so that a channel is formed on the surface of the p type base region 3 which is in contact with the trench 6. Electrons injected from the source electrode 11 flow to the n⁻ type drift layer 2 through the n⁺ type source region 4 and the channel formed in the p type base region 3. Accordingly, electric current can be provided between the source electrode. 11 and the drain electrode 13.

Furthermore, in the present embodiment, the impurity concentration of the lightly doped region 10b of the p type deep layer 10 is reduced so that application of a gate voltage to the gate electrode 9 in an on state forms an inversion layer at portions of the lightly doped region 10b on the side surface and bottom portion of the trench 6. This makes it possible to allow electric current flowing through the channel to flow not only through a portion of the n⁻ type drift layer 2 positioned between the p type deep layers 10 but also through the inversion layer formed in the lightly doped region 10b. As shown in a broken line in FIG. 3, a JFET region formed between two p type deep layers 10 adjacent to each other therefore becomes narrow. As a result, a JFET resistance can be reduced and a reduction in on-resistance can be achieved.

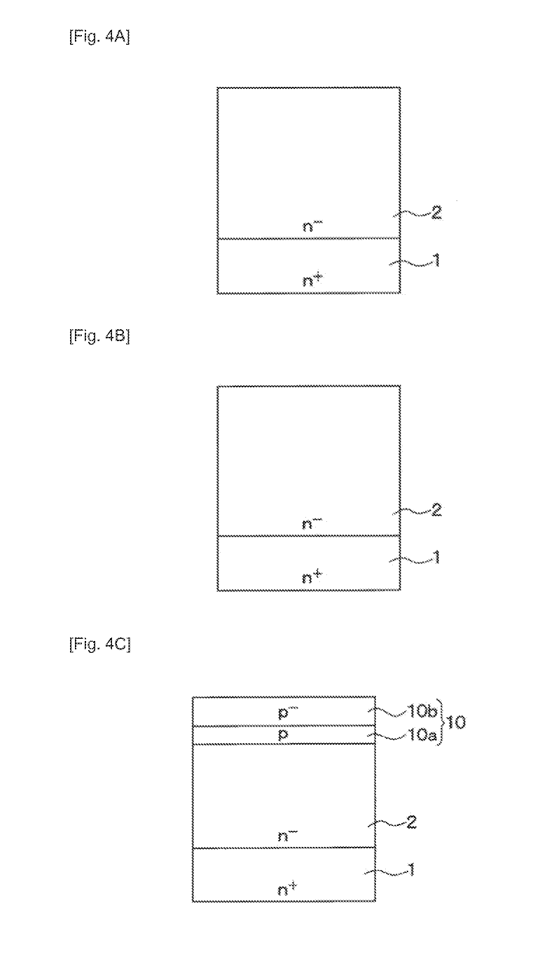

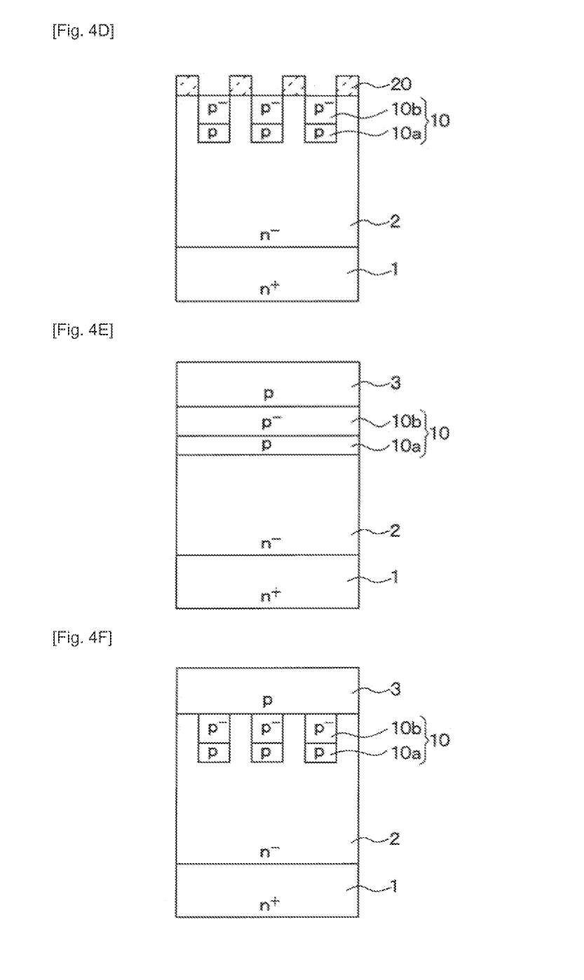

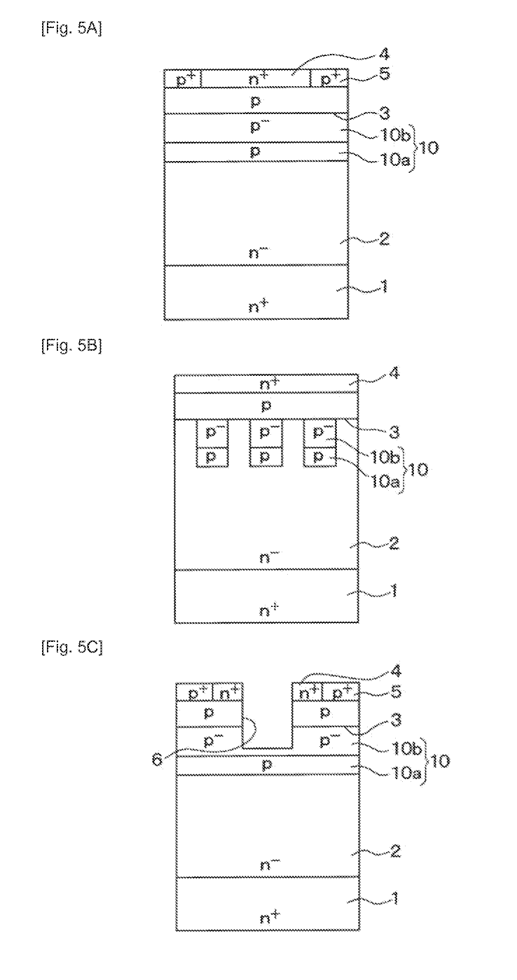

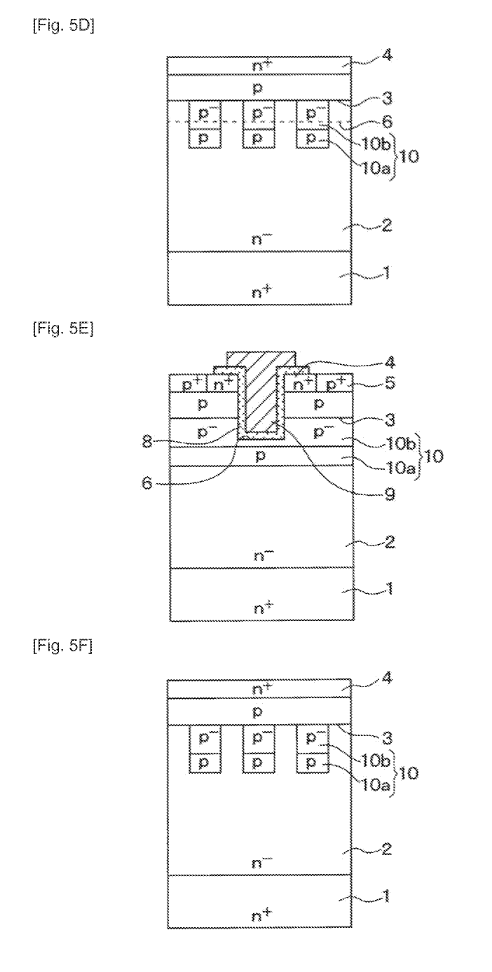

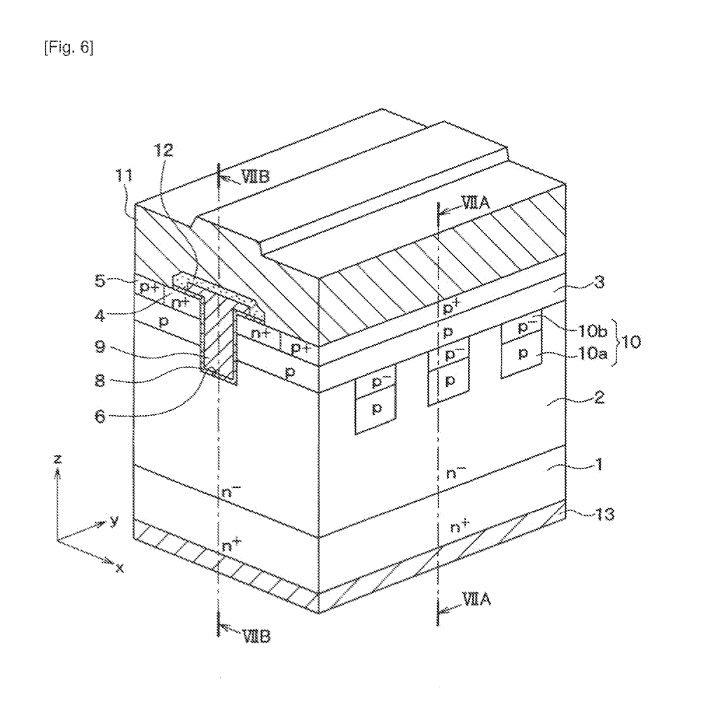

Next, a manufacturing method of the MOSFET having a trench gate structure as shown in FIG. 1 will be described. FIGS. 4A to 4F and 5A to 5F are cross-sectional views showing manufacturing steps of the MOSFET having a trench gate structure as shown in FIG. 1. In each of FIGS. 4A to 4F and 5A to 5F, cross-sectional views (area corresponding to FIG. 2B) taken along the line IIB-IIB in parallel with the xz plane in FIG. 1 are shown on the left side, while cross-sectional views (area corresponding to FIG. 2D) taken along the line IID-IID in parallel with the yz plane in FIG. 1 are shown on the right side. The description will next be made referring to these drawings.

(Step Shown in FIGS. 4A and 4B)

First, an n⁺ type substrate 1 having, for example, a concentration of n type impurities, such as phosphorous, of 1.0×10¹⁹/cm³ and a thickness of about 300 micrometer is prepared. On the surface of the n⁺ type substrate 1, an n⁻ type drift layer 2 having, for example, a concentration of n type impurities, such as phosphorus, of from 3.0×10¹⁵/cm³ to 7.0×10¹⁵/cm³ and a thickness of about 15 micrometer and made of SiC is formed by epitaxial growth.

(Step Shown in FIGS. 4C and 4D)

After formation of a mask 20 made of LTO or the like on the surface of the n⁻ type drift layer 2, the mask 20 is opened at a predetermined formation region of a p type deep layer 10 through photolithography. Then, p type impurities (such as boron or aluminum) are implanted from above the mask 20 and are activated to form the p type deep layer 10. At this time, a heavily doped region 10a having, for example, a boron or aluminum concentration of from 1.0×10¹⁷/cm³ to 1.0×10¹⁹/cm³ and a lightly doped region 10b having, for example, a boron or aluminum concentration of from 1.0×10¹⁵/cm³ to 1.0×10¹⁷/cm³ are formed by changing the concentration of boron or aluminum and ion injection energy while using the mask 20. Then, the mask 20 is removed.

(Step Shown in FIGS. 4E and 4F)

A p type base region 3 is formed by the epitaxial growth of a p type impurity layer having, for example, a concentration of p type impurities, such as boron or aluminum, of from 5.0×10¹⁵ to 5.0×1.0¹⁶/cm³ and a thickness of about 2.0 micrometer on the surface of the n⁻ type drift layer 2.

(Step Shown in FIGS. 5A and 5B)

Then, after formation of a mask (not illustrated) made of, for example, LTO on the p type base region 3, photolithography is conducted to open the mask at a predetermined formation region of an N⁺ type source region 4. After that, n type impurities (such as nitrogen) are implanted.

Then, after removal of the mask used previously, another mask (not illustrated) is formed. Photolithography is performed to open the mask at a predetermined formation region of a p⁺ type body layer 5. Then, p type impurities (such as boron or aluminum) are implanted,

The ions thus implanted are then activated to form an type source region 4 having, for example, a concentration (surface concentration) of n type impurities such as phosphorus of 1.0×10²¹/cm³ and a thickness of about 0.3 micrometer and a p⁺ type contact layer 5 having, for example, a concentration (surface concentration) of p type impurities such as boron or aluminum of about 1.0×10²¹/cm³ and a thickness of about 0.3 micrometer. After that, the mask is removed.

(Step Shown in FIGS. 5C and 5D)

After formation of an etching mask, which is not illustrated, on the p type base region 3, the n⁺ type source region 4, and the p⁺ type contact layer 5, the etching mask is opened at a predetermined formation region of a trench 6. Then, anisotropic etching is performed with the etching mask, followed by isotropic etching or sacrificial oxidation if needed to form a trench 6. After this, the etching mask is removed.

(Step Shown in FIGS. 5E and 5F)

A gate oxide film formation step is performed to form a gate oxide film 8 on the entire surface of the substrate including the inside of the trench 6. More specifically, the gate oxide film 8 is formed by gate oxidization (thermal oxidization) by a pyrogenic method using a wet atmosphere. Next, an about 440-nm thick polysilicon layer doped with n type impurities is formed on the surface of the gate oxide film 8 at a temperature of, for example, 600 degrees C. and then, an etch back step or the like is performed to leave the gate oxide film 8 and the gate electrode 9 in the trench 6.

Steps following the above step are not illustrated because they are similar to conventional steps. After formation of an interlayer insulating film 12, the interlayer insulating film 12 is patterned to form contact holes connected to the n⁺ type source region 4 or the p⁺ type contact layer 5 and at the same time, to form contact holes connected to the gate electrode 9 on another cross section. Next, after a film of an electrode material is formed to fill the contact holes therewith, it is patterned to form a source electrode 11 and a gate wiring. A drain electrode 13 is formed on the back surface side of the n⁺ type substrate 1. As a result,the MOSFET shown in FIG. 1 is completed.

In the above-described manufacturing method, the heavily doped region 10a and the lightly doped region 10b of the p type deep layer 10 can be formed with the same mask 20, making it possible to share a mask and simplify the manufacturing steps of a SiC semiconductor device.

As described above, in the present embodiment, the impurity concentration of the lightly doped region 10b of the p type deep layer 10 is decreased and when a gate voltage is applied to the gate electrode 9 in an on state, an inversion layer is formed at a portion of the lightly doped region 10b located on the side surface and bottom portion of the trench 6. Electric current flowing through a channel can therefore flow not only through a portion of the n⁻ type drift layer 2 positioned between the p type deep layers 10 but also through the inversion layer formed in the lightly doped region 10b. Accordingly, a JFET resistance in a JFET region formed between two p type deep layers 10 adjacent to each other can be reduced and therefore a reduction in on-resistance can be achieved.

### Second Embodiment

A second embodiment will next be described. The SiC semiconductor device of this embodiment is different from that of the first embodiment in the structure of the p type deep layer 10. Since they are similar in the fundamental structure, only portions different from the first embodiment will next be described.

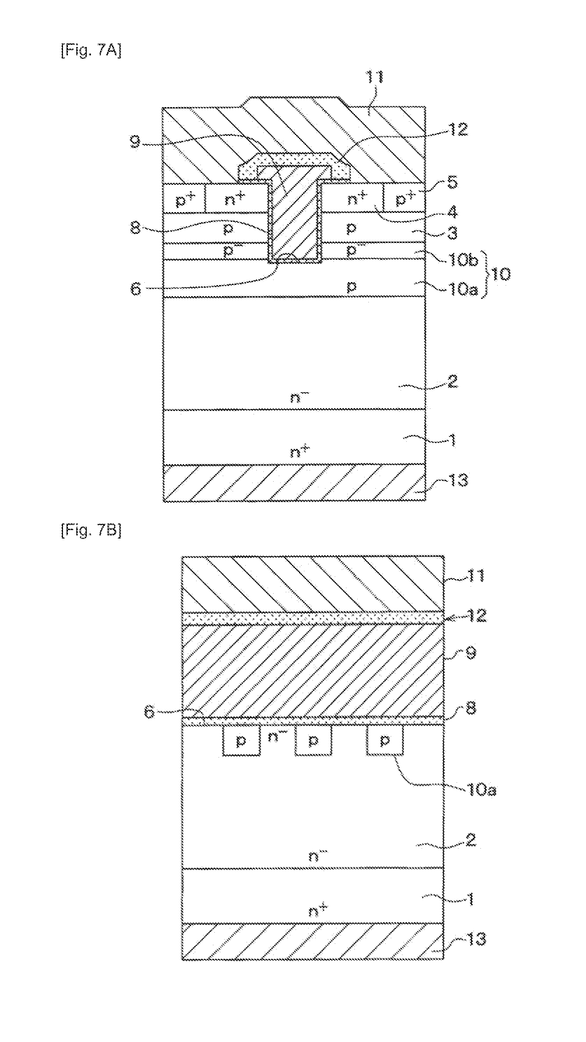

FIG. 6 is a perspective cross-sectional view of the SiC semiconductor device according to this embodiment. FIG. 7A is a cross-sectional view taken along the line VIIA-VIIA in parallel with the xz plane in FIG. 6 and FIG. 713 is a cross-sectional view taken along the line VIIB-VIIB in parallel with the yz plane in FIG. 6.

In this embodiment, as shown in FIG. 6 and FIGS. 7A and 713, the depth of the lightly doped region 10b of the p type deep layer 10 is made shallower than that in the first embodiment and the bottom of the trench 6 is in contact with the heavily doped region 10a. In such a structure, when a voltage is applied to the gate electrode 9, inversion occurs only in the lightly doped region 10b of the p type deep layer 10 located on the side surface of the trench 6 and no inversion layer is formed at the bottom portion of the trench 6. It is however possible to allow electric current to flow through at least an inversion layer formed in the lightly doped region 10b positioned on the side surface of the trench 6. Compared with the first embodiment, the structure of the present embodiment is less effective, but a JFET resistance in a JFET region formed between two p type deep layers 10 adjacent to each other can be reduced and therefore, a reduction in on-resistance can be achieved.

A manufacturing method of the SiC semiconductor device of the present embodiment is basically similar to that of the first embodiment. It is only necessary to change the ion implantation conditions employed in the first embodiment for the formation of the p type deep layer 10 shown in FIGS. 4C and 4D and expand the heavily doped region 10a to a position contiguous to the bottom portion of the trench 6.

### Third Embodiment

A third embodiment will next he described. The SiC semiconductor device of this embodiment is also different from that of the first embodiment in the structure of the p type deep layer 10. Since they are similar in the fundamental structure, only portions different from the first embodiment will next be described.

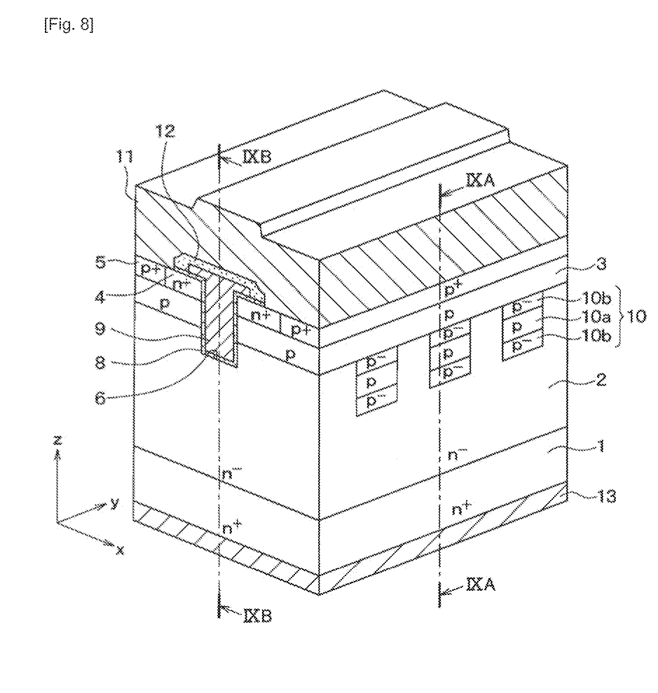

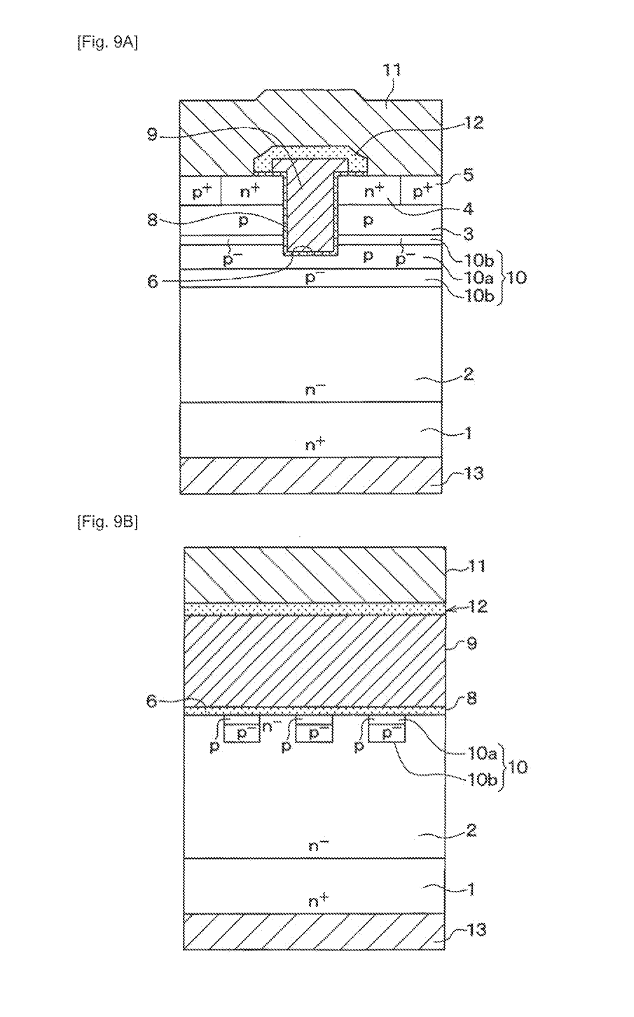

FIG. 8 is a perspective cross-sectional view of the SiC semiconductor device according to the present embodiment. FIG. 9A is a cross-sectional view taken along the line IXA-IXA in parallel with the xz plane in FIG. 8 and FIG. 9B is a cross-sectional view taken along the line IXB-IXB in parallel with the yz plane in FIG. 8.

In this embodiment, as shown in FIG. 8 and FIGS. 9A and 9B, the lower layer portion and the upper layer portion of the p type deep layer 10 are formed as a lightly doped region 10b, while the intermediate layer portion is formed as the heavily doped region 10a. In such a structure, when a gate voltage is applied to the gate electrode 9, inversion occurs only in the lightly doped region 10b of the p type deep layer 10 located on the side surface of the trench 6 and no inversion layer is formed at the bottom portion of the trench 6. It is however possible to allow electric current to flow through at least an inversion layer formed in the lightly doped region 10b positioned on the side surface of the trench 6. Compared with the first embodiment, the structure of the present embodiment is less effective, but a JFET resistance in a JFET region formed between two p type deep layers 10 adjacent to each other can be reduced and therefore, a reduction in on-resistance can be achieved.

In the structure of the present embodiment, the lower layer portion of the p type deep layer 10 serves as the lightly doped region 10b, but since the heavily doped region 10a is formed at the bottom portion of the trench 6, this heavily doped region 10a can relax an electric field concentration in the gate oxide film 8 positioned at the bottom portion of the trench 6. As a result, a breakdown voltage can be achieved.

A manufacturing method of the SiC semiconductor device of the present embodiment is also basically similar to that of the first embodiment. It is only necessary to change the ion implantation concentration in a depth direction upon formation of the p type deep layer 10 as shown in FIG. 4C and 4D, thereby permitting the lower layer portion and the upper layer portion to serve as the lightly doped region 10b and permitting the intermediate layer portion to serve as the heavily doped region 10a.

### Fourth Embodiment

A fourth embodiment will next be described. The SiC semiconductor device of this embodiment is also different from that of the first embodiment in the structure of the p type deep layer 10. Since they are similar in the fundamental structure, only portions different from the first embodiment will next be described.

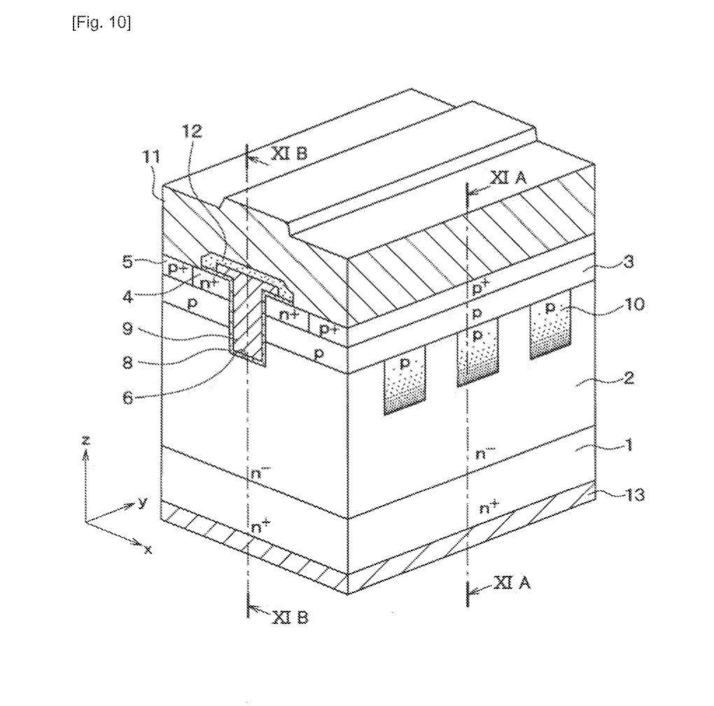

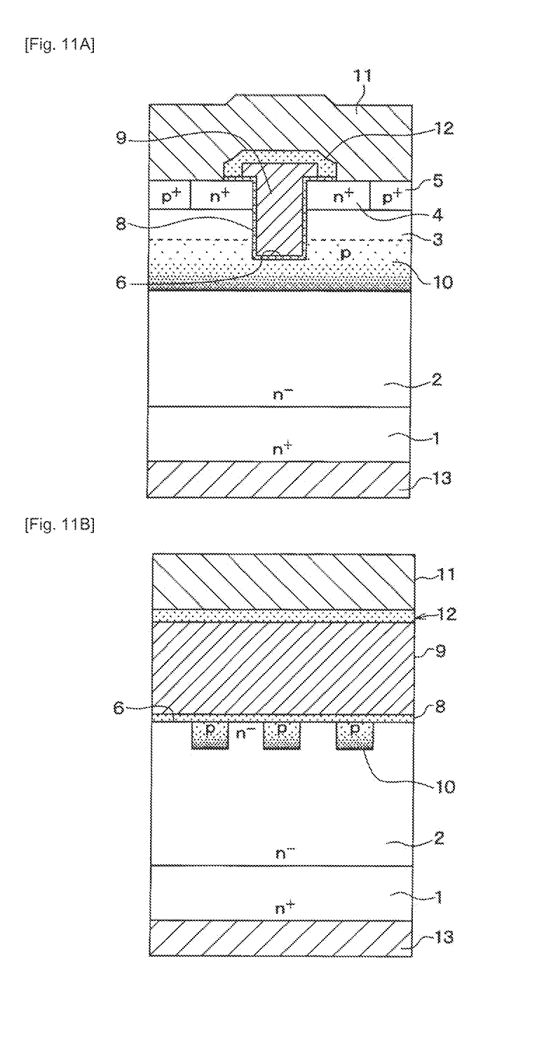

FIG. 10 is a perspective cross-sectional view of the SiC semiconductor device according to the present embodiment, FIG. 11A is a cross-sectional view taken along the line XIA-XIA in parallel with the xz plane in FIG. 10 and FIG. 11B is a cross-sectional view taken along the line XIB-XIB in parallel with the yz plane in FIG. 10.

In the structure of the present embodiment as illustrated in FIG. 10 and FIGS. 11A and 11B, an impurity concentration gradient is provided in the depth direction of the p type deep layer 10 and with a decrease in the depth of the p type deep layer 10, the impurity concentration becomes lower gradually. Even when such a structure is employed, application of a gate voltage to the gate electrode 9 leads to the formation of an inversion layer at a portion of the p type deep layer 10 located on the side surface or bottom portion of the trench 6. Similar to the first embodiment, a JFET resistance in a JFET region formed between two p type deep layers 10 adjacent to each other can be reduced and therefore a reduction in on-resistance can be achieved. Also in this embodiment, when a gate voltage is applied to the gate electrode 9, an inversion layer is sometimes formed only in a portion of the p type deep layer 10 located on the side surface of the trench 6, which depends on the impurity concentration gradient of the p type deep layer 10. In this case, as described in the second embodiment, the structure of the present embodiment is less effective than that of the first embodiment, but a similar effect to that of the first embodiment can be achieved.

The manufacturing method of the SiC semiconductor device having a structure of the present embodiment is basically similar to that of the first embodiment. It is only necessary to change the ion implantation concentration employed in the first embodiment for the formation of the p type deep layer 10, which is shown in FIGS. 4C and 4D, so as to gradually reduce the dosage of the impurities upon ion implantation with a decrease in the depth.

### Fifth Embodiment

A fifth embodiment will next be described. The SiC semiconductor device of this embodiment is also different from that of the first embodiment in the structure of the p type deep layer 10. Since they are similar in the fundamental structure, only portions different from the first embodiment will next be described.

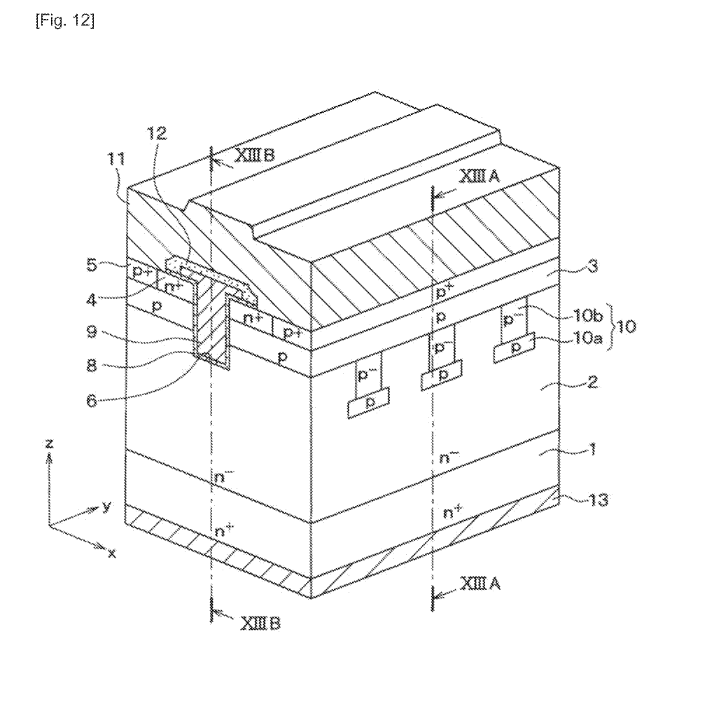

FIG. 12 is a perspective cross-sectional view of the SiC semiconductor device according to the present embodiment. FIG. 13A is a cross-sectional view taken along the line XIIIA-XIIIA in parallel with the xz plane in FIG. 12 and FIG. 13B is a cross-sectional view taken along the line in parallel with the yz plane in FIG. 12.

In this embodiment, as illustrated in FIG. 12 and FIGS. 13A and 13B, the width of the p type deep layer 10 is changed in the depth direction of the p type deep layer 10. The width of a heavily doped region 10a located at the lower layer portion of the p type deep layer 10 is set in consideration of breakdown voltage, while the width of a lightly doped region 10b located at the upper layer portion is made smaller than that of the heavily doped region 10a. When such a structure is employed, the width of the n⁻ type drift layer 2 can be made wider in proportion to a decrease in the width of the lightly doped region 10b compared with the first embodiment so that a current path can be widened even in a region which will not be an inversion layer when a gate voltage is applied to the gate electrode 9. Accordingly, a JFET resistance in a JFET region formed between two p type deep layers 10 adjacent to each other can be reduced further and therefore, a further reduction in on-resistance can be achieved.

A manufacturing method of the SiC semiconductor device having the structure of the present embodiment is basically similar to that of the first embodiment, but upon formation of the p type deep layer 10 which is shown in FIGS. 4C and 4D, ion implantation is performed after two masks 20 different in opening width are formed respectively. For example, first, a mask 20 opened in a predetermined formation region of the lightly doped region 10b is formed and p type impurities are implanted to form the lightly doped region 10b. After removal of the mask 20, another mask 20 opened in a predetermined formation region of the heavily doped region 10a is formed and p type impurities are implanted to form the heavily doped region 10a. It is recommended to form the heavily doped region 10a and the lightly doped region 10b by implanting p type impurities at different dosages and set the p type impurity concentration lower in the lightly doped region 10b than in the heavily doped region 10a.

### Sixth Embodiment

A sixth embodiment will next be described. The SiC semiconductor device of this embodiment is also different from that of the first embodiment in the structure of the p type deep layer 10. Since they are similar in the fundamental structure, only portions different from the first embodiment will next be described.

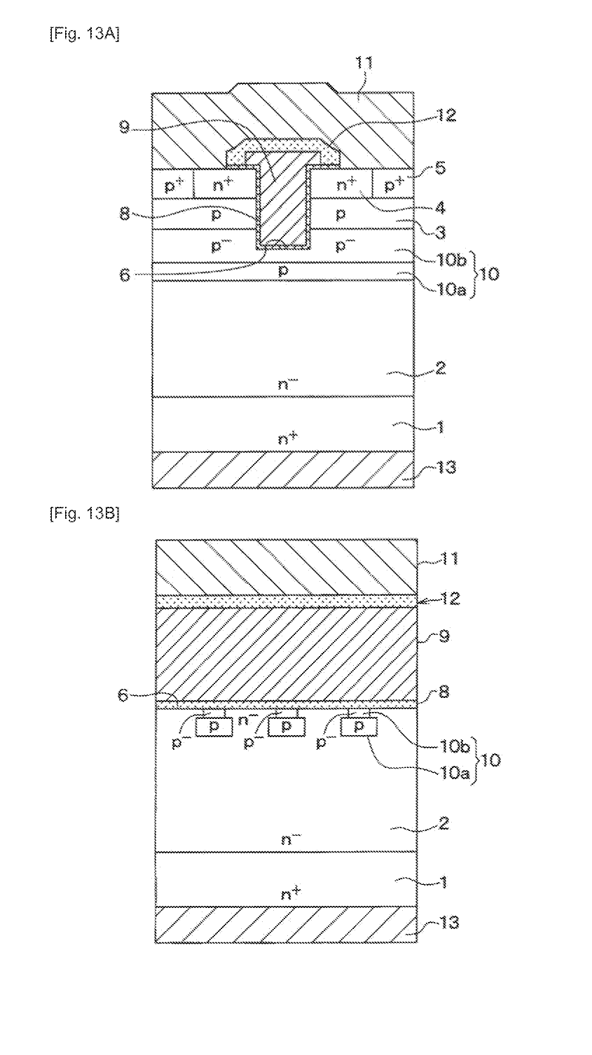

FIG. 14 is a perspective cross-sectional view of the SiC semiconductor device according to the present embodiment. FIG. 15A is a cross-sectional view taken along the line XVA-XVA in parallel with the xx plane in FIG. 14 and FIG. 15B is a cross-sectional view taken along the line XVB-XVB in parallel with the yz plane in FIG. 14.

In the present embodiment, as shown in FIG. 14 and FIGS. 15A and 15B, the width of the p type deep layer 10 is changed in the depth direction of the p type deep layer 10 as in the fifth embodiment and the width of the bottom portion of the heavily doped region 10a located at the lower layer portion of the p type deep layer 10 is set at a width in consideration of a breakdown voltage and with a decrease in the depth of the p type base layer 10 from this position, the width is decreased gradually. Even if such a structure is employed, the width of the n⁻ type drift layer 2 can be widened in proportion to a decrease in the width of the lightly doped region 10b compared with the first embodiment so that even in a region which will not be an inversion layer when a gate voltage is applied to the gate electrode 9, a current path can be widened. Accordingly, a JFET resistance in a JFET region formed between two p type deep layers 10 adjacent to each other can be reduced further and therefore, a further reduction in on-resistance can be achieved.

A manufacturing method of the SiC semiconductor device having the structure of the present embodiment is basically similar to that of the first embodiment. It is only necessary to implant p type impurities by oblique ion implantation using the mask 20 upon formation of the p type deep layer 10 which is shown in FIGS. 4C and 4D, thereby forming the p type deep layer 10 in an oblique direction.

### Seventh Embodiment

A seventh embodiment will next be described. The SiC semiconductor device of this embodiment is also different from that of the first embodiment in the structure of the p type deep layer 10. Since they are similar in the fundamental structure only portions different from the first embodiment will next be described.

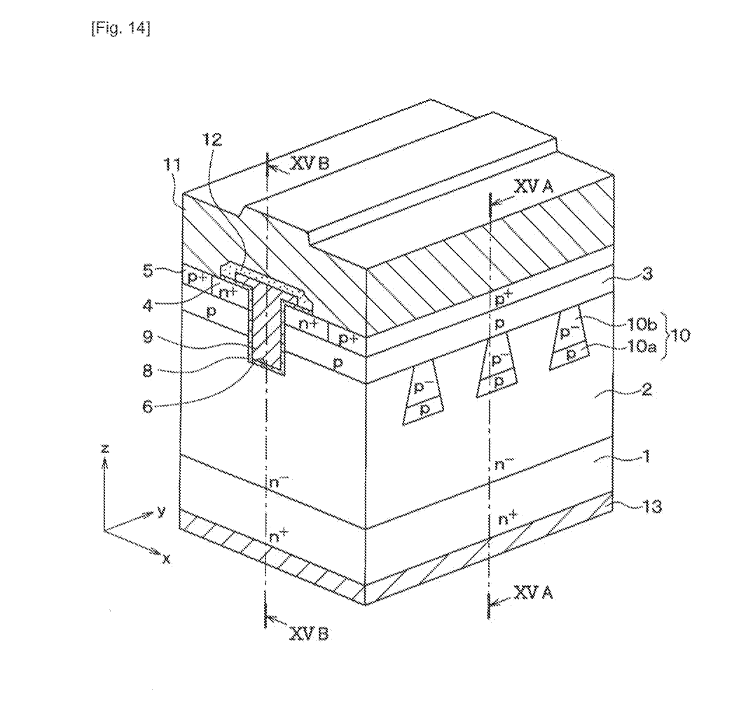

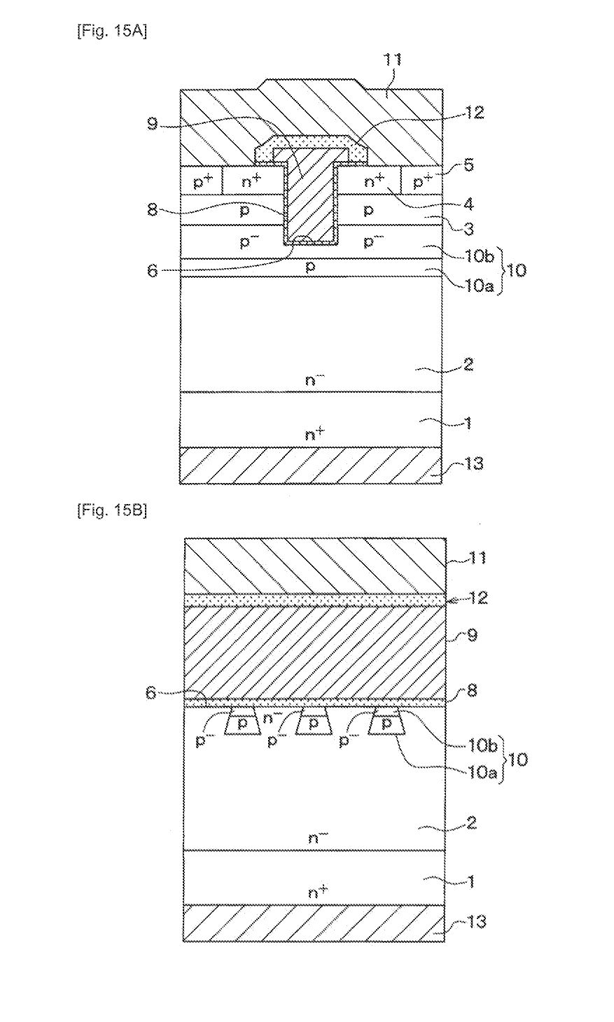

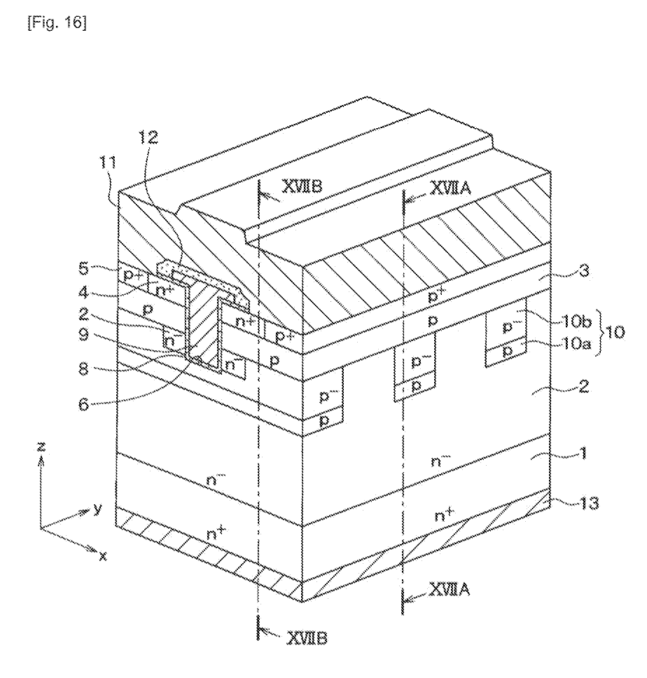

FIG. 16 is a perspective cross-sectional view of the SiC semiconductor device according to the present embodiment. FIG. 17A is a cross-sectional view taken along the line XVIIA-XVIIA in parallel with the xz plane in FIG. 16 and FIG. 17B is a cross-sectional view taken along the line XVIIB-XVIIB in parallel with the yz plane in FIG. 16.

In the present embodiment, as shown in FIG. 16 and FIGS. 17A and 17B, the p type deep layer 10 has a two-layer structure with the heavily doped region 10a and the lightly doped region 10b. At the same time, the lightly doped region 10b is not formed on at least a portion of the side surface of the trench 6 and the n type drift layer 2 has been left on the side surface of the trench 6 as a first conductivity type layer.

When such a structure is employed, current flow of the side surface of the trench can be ensured by the n⁻ type drift layer 2, while that of a part of the side surface of the trench 6 or the bottom thereof can be ensured by the formation of an inversion layer. Accordingly, similar to the first embodiment, a JFET resistance in a JFET region formed between two p type deep layers 10 adjacent to each other can be reduced further and therefore, a further reduction in on-resistance can be achieved,

In this embodiment compared with the first embodiment, the n⁻ type drift layer 2 has been left on the side surface of the trench 6 and the p type deep layer 10 is formed below the n⁻ type drift layer 2 on the side surface of the trench 6. A similar structure can also be applied to the second to sixth embodiments.

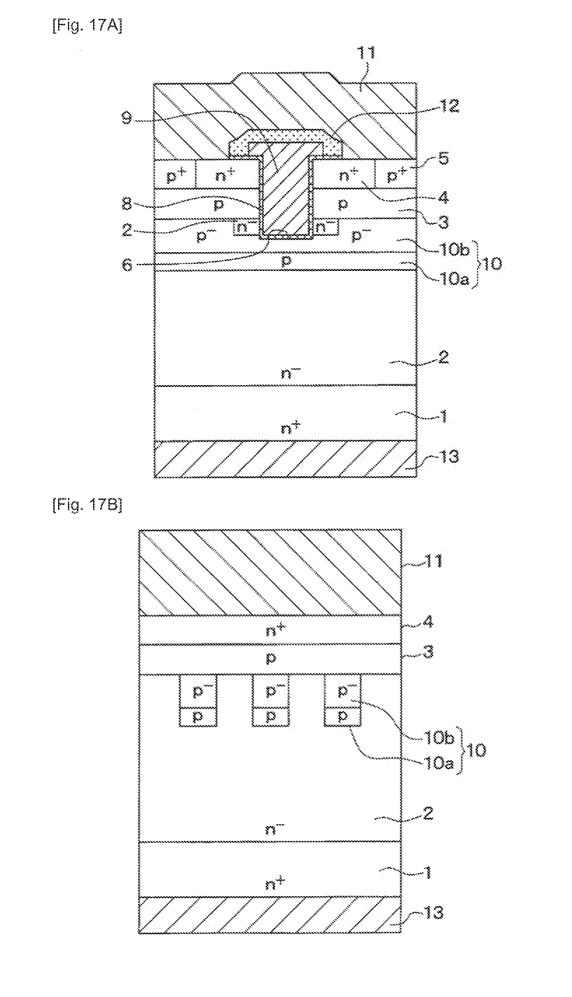

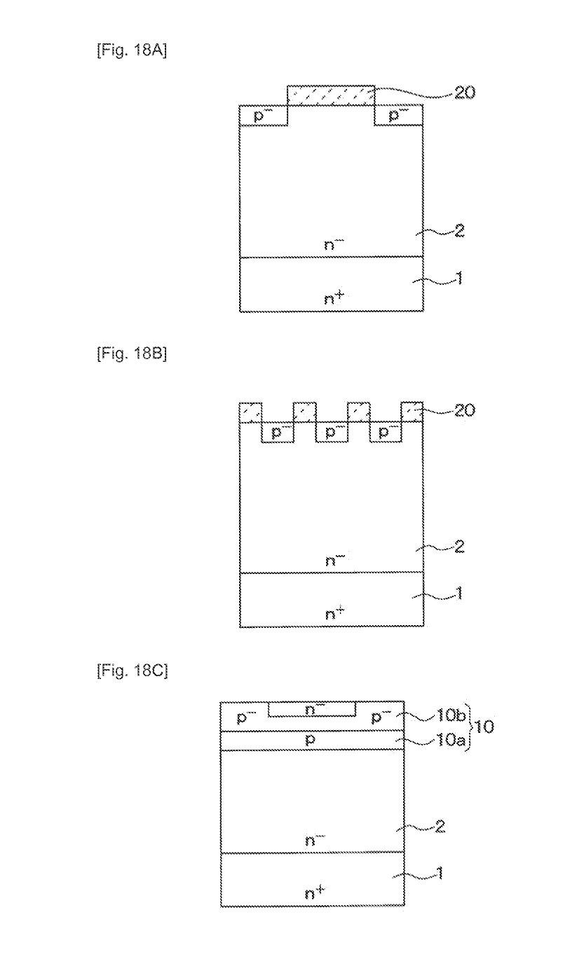

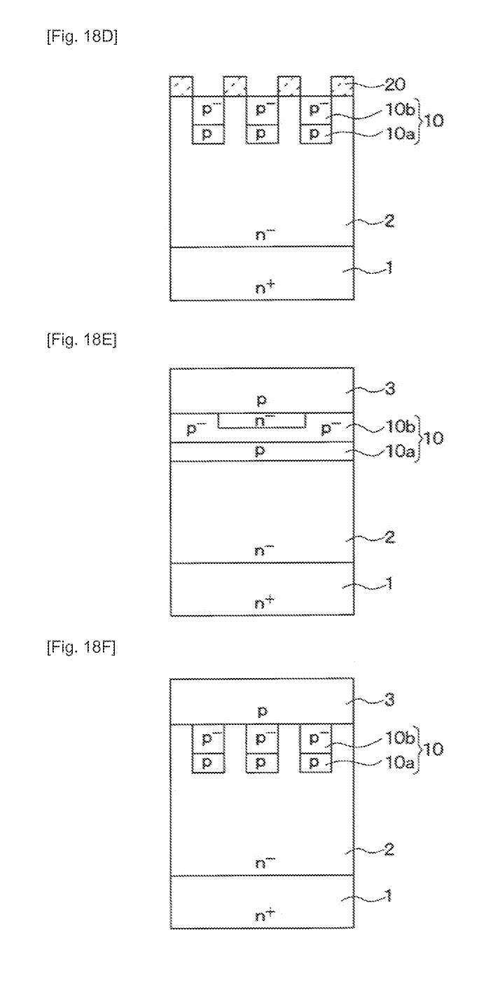

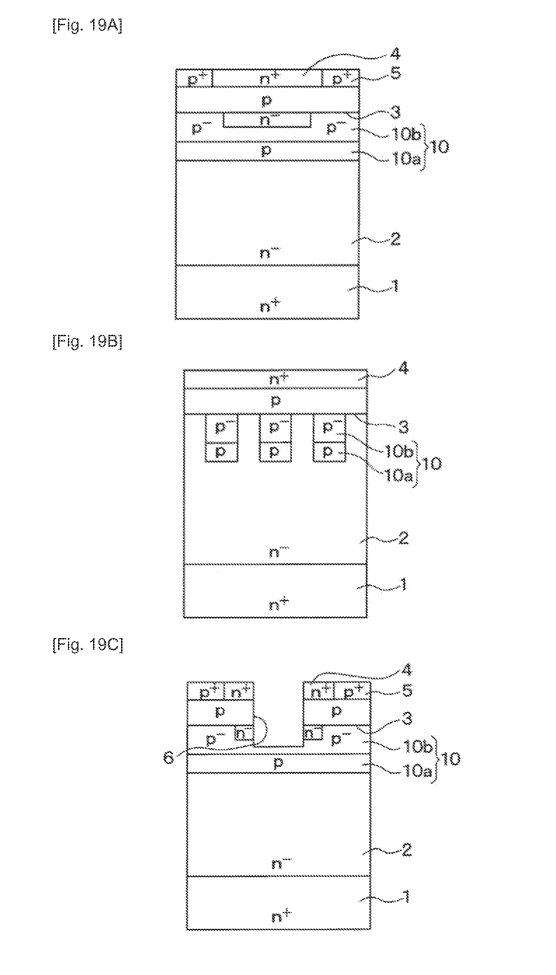

Next, a manufacturing method of the SiC semiconductor device of the present embodiment will be described. FIGS. 18A to 18F and 19A to 19F are cross-sectional views showing manufacturing steps of the SiC semiconductor device of the present embodiment. In each of FIGS. 18A to 18F and 19A to 19F, a cross-sectional view (area corresponding to FIG. 17A) taken along the line XVIIA-XVIIA in parallel with the xz plane in FIG. 16 is shown on the left side and a cross-sectional view (area corresponding to FIG. 17B) taken along the line XVIIB-XVIIB in parallel with the yz plane in FIG. 16 is shown on the right side. The manufacturing method of the SiC semiconductor device according to the present embodiment is basically similar to that of the first embodiment so that only portions different from the first embodiment will next be described.

First, a step similar to that of FIGS. 4A and 4B is performed to form an n⁻ type drift layer 2 by epitaxial growth on the surface of the n* type semiconductor substrate 1. Then, in the step shown in FIGS. 1.8A and 18B, after formation of a mask 20 made of LTO or the like on the surface of the n⁻ type drift layer 2, photolithography is performed to open an upper layer portion of a lightly doped region 10b, among predetermined formation regions of a p type deep layer 10. Upon this opening, the mask 20 is remained unopened in a region where a trench 6 is to he formed in a later step and a region therearound. The upper layer portion of the lightly doped region 10b is formed by implanting p type impurities (such as boron or aluminum) from above the mask 20. Then, as illustrated in FIGS. 18C and 18D, the mask 20 is patterned again by photolithography to open all the predetermined formation regions of the p type deep layer 10. This means that the mask 20 is removed even from areas corresponding to a region in which the trench 6 is to be formed later and a region therearound. By implanting p type impurities (such as boron or aluminum) from above the mask 20 and activating them, a remaining portion of the lightly doped region 10b and a heavily doped region 10a are formed. After that, in the steps shown in FIG. 18E and 18F and FIGS. 19A to 19F, steps similar to those shown in FIGS. 4E and 4F and FIGS. 5A to 5F described in the first embodiment are performed to manufacture the SiC semiconductor device of the present embodiment.

### Eighth Embodiment

An eighth embodiment will next be described. The SiC semiconductor device of this embodiment has a structure capable of reducing the on resistance further compared with that of the first embodiment. Since they are similar in the fundamental structure, only portions different from the first embodiment will next be described.

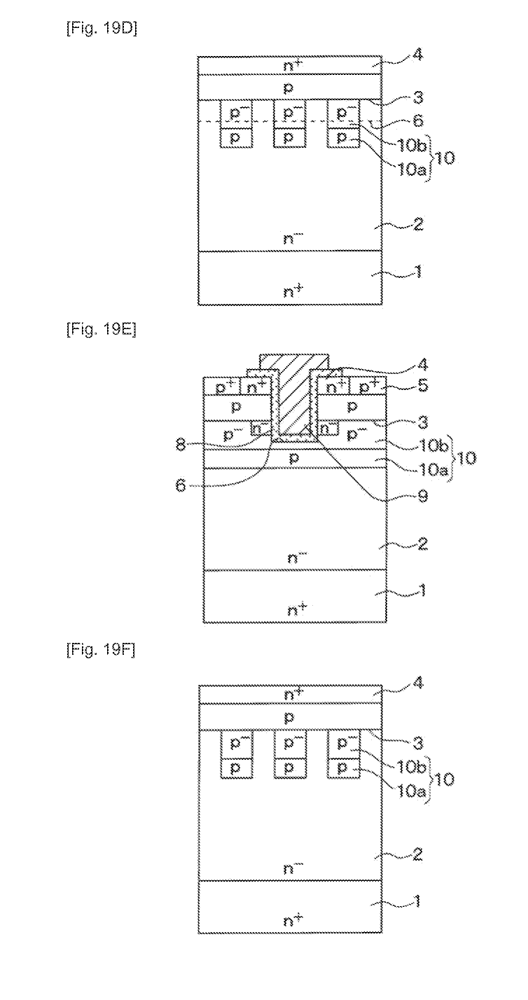

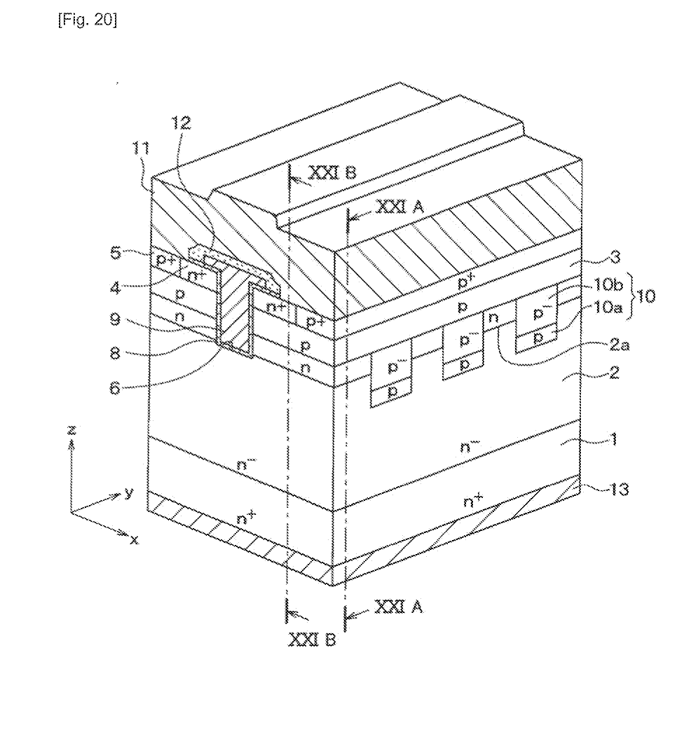

FIG. 20 is a perspective cross-sectional view of the SiC semiconductor device according to the present embodiment. FIG. 21A is a cross-sectional view taken along the line XXIA-XXIA in parallel with the xz plane in FIG. 20 and FIG. 21B is a cross-sectional view taken along the line XXIB-XXIB in parallel with the yz plane in FIG. 20.

In the present embodiment, as shown in FIG. 20 and FIGS. 21A and 21B, a current diffusion layer 2a is formed by setting high the n type impurity concentration on the surface side of the n⁻ type drift layer 2, that is, on the side opposite to the n⁺ type semiconductor substrate 1. The current diffusion layer 2a is provided in order to widen a current flowing range in an on state and the current diffusion layer 2a has an impurity concentration of, for example, from 5.0×10¹⁶ to 1.5×10¹⁷/cm³ and has a thickness of from 0.3 to 0.7 micrometer.

Described specifically, when a gate voltage is applied to the gate electrode 9 in an on state, a channel is formed on the surface of the p type base region 3 contiguous to the trench 6 and electrons injected from the source electrode 11 flow from the n⁺ type source region 4, pass through the channel formed on the p type base region 3, and then reach the current diffusion layer 2a of the n⁻ type drift layer 2. As a result, a current flowing range becomes wider in the low-resistance current diffusion layer 2a and electric current flows even to a position distant from the trench gate structure, which contributes to a further reduction in on-resistance.

Thus, the p type deep layer 10 comprised of the heavily doped region 10a and the lightly doped region 10b may be equipped with the current diffusion layer 2a. This enables to achieve a further reduction in on-resistance.

A manufacturing method of the SiC semiconductor device having the structure of the present embodiment is basically similar to that of the first embodiment. It is only necessary to form the current diffusion layer 2a by increasing, at the final stage of the formation step of the n⁻ type drift layer 2 shown in FIGS. 4A and 4B, the concentration of impurities to be doped upon growth of the layer.

Here, the SiC semiconductor device having the structure of the first embodiment and equipped with the current diffusion layer 2a further is described, but the SiC semiconductor devices having the structure of the second to the seventh embodiments may be equipped with the current diffusion layer 2a. Also in this case, it is only necessary to form the current diffusion layer 2a by increasing, at the final stage of the formation step of the n⁻ type drift layer 2, the concentration of impurities to be doped upon epitaxial growth of the layer.

### Ninth Embodiment

A ninth embodiment will next be described. In this embodiment, a manufacturing method of the SiC semiconductor device having the structure of the first embodiment, which method is different from that employed in the first embodiment, will be described.

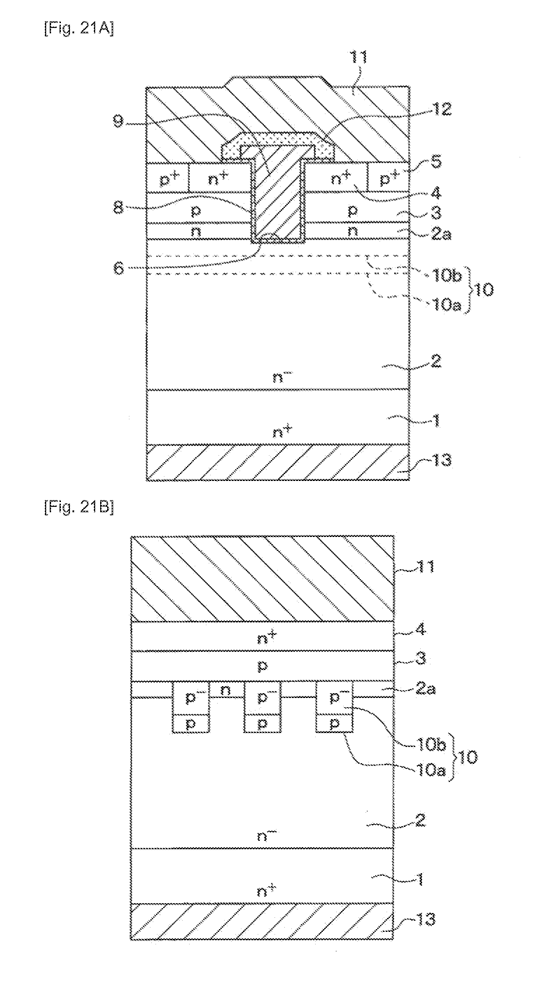

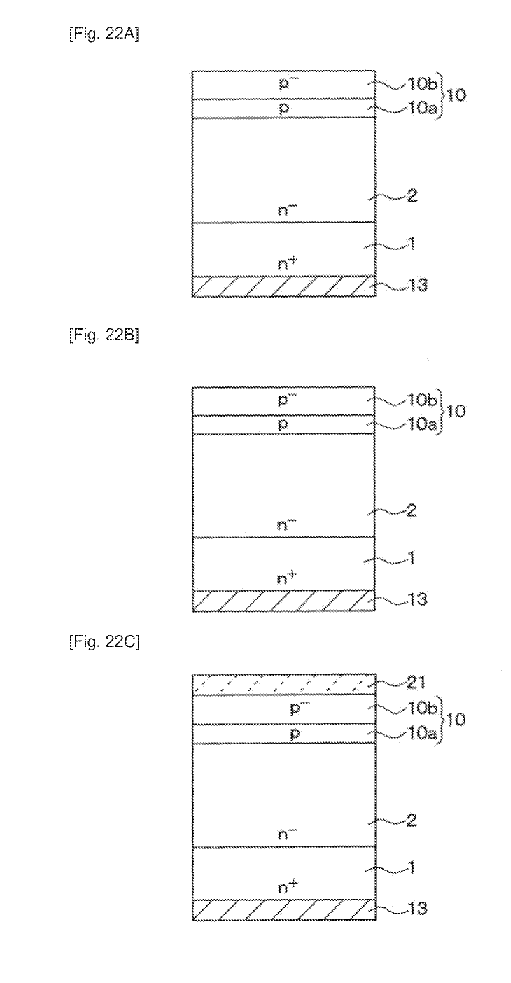

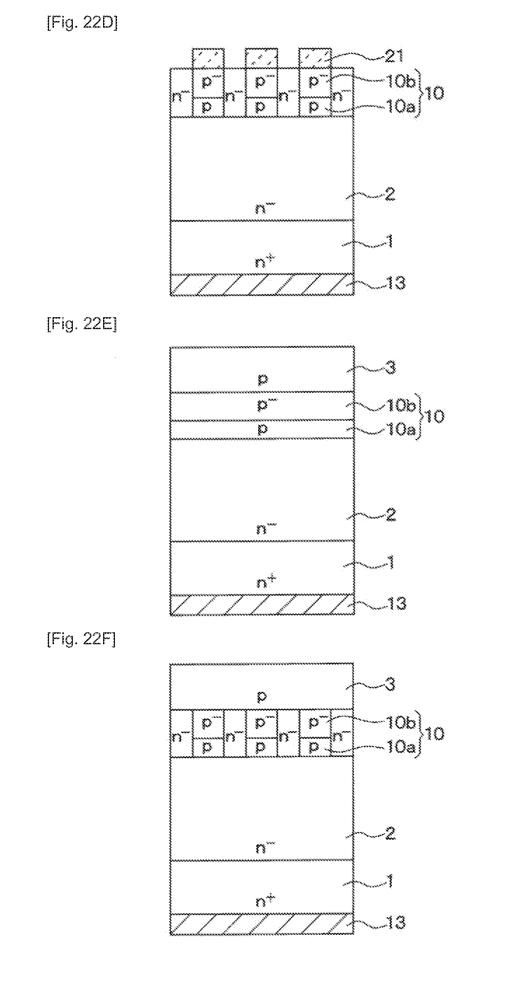

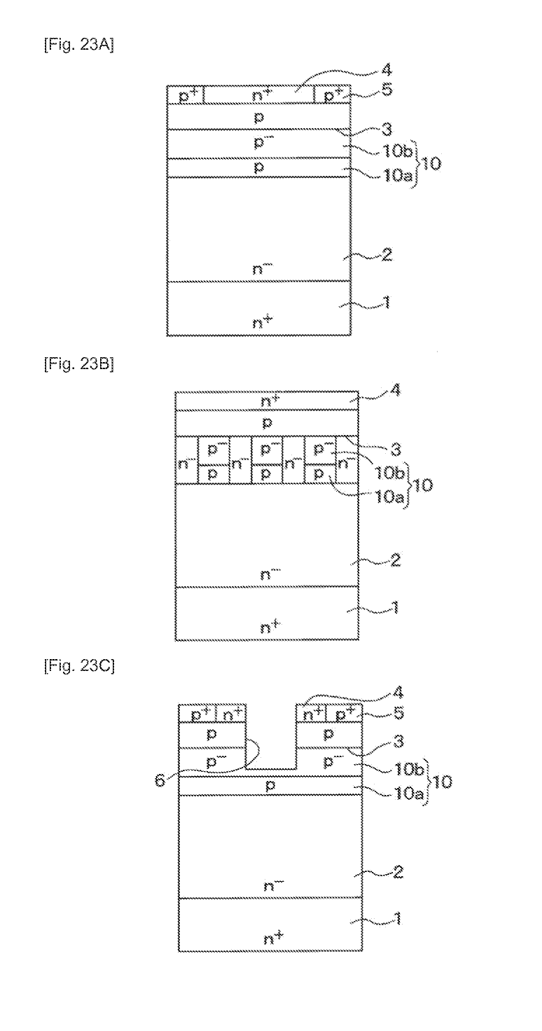

FIGS. 22A to 22F and 23A to 23F are cross-sectional views showing manufacturing steps of the SiC semiconductor device according to the present embodiment. In each of FIGS. 22A to 22F and 23A to 23F, a cross-sectional view (area corresponding to FIG. 2B) taken along the line IIB-IIB in parallel with the xz plane in FIG. 1 is shown on the left side and a cross-sectional view (area corresponding to FIG. 2D) taken along the line IID-IID in parallel with the yz plane in FIG. 1 is shown on the right side. The manufacturing method of the SiC semiconductor device of the present embodiment will next be described referring to these drawings.

In the step shown in FIGS. 22A and 22B, after formation of the n⁻ type drift layer 2 by epitaxial growth on the surface of the re type substrate 1, a p type deep layer 10, more specifically, a heavily doped region 10a and a lightly doped region 10b are formed successively by the epitaxial growth on the surface of the n⁻ type drift layer 2. Then, in the step shown in FIGS. 22C and 22D, a mask 21 is placed and n type impurities (such as nitrogen) are implanted through this mask to partially invert the p type deep layer 10 to an n type SiC, thereby forming a region of the n⁻ type drift layer 2 sandwiched between two p type deep layers 10 adjacent to each other. After that, in the steps shown in FIG. 22E and 22F and FIGS. 23A to 23F, steps similar to those shown in FIGS. 4E and 4F and FIGS. 5A to 5F described in the first embodiment are performed to manufacture a SiC semiconductor device having a structure similar to that of the first embodiment.

Thus, it is possible to form a region of the n type drift layer 2 sandwiched between two adjacent p type deep layers 10 after formation of the p type deep layer 10. According to such a manufacturing method, the p type deep layer 10 can be formed by epitaxial growth not by ion implantation so that the heavily doped region 10a can he formed as a region having a higher impurity concentration or a region of the n⁻ type drift layer 2 sandwiched between two adjacent p type deep layers 10 can be formed as a region having a higher concentration than a region located below the p type deep layer 10.

In the above description, the SiC semiconductor device having the structure of the first embodiment is manufactured by forming the p type deep layer 10 and then forming a region of the n⁻ type drift layer 2 sandwiched between two adjacent p type deep layers 10. A similar manufacturing method can be applied to the SiC semiconductor devices having the structures of the second to eighth embodiments. However, when as in the fifth embodiment, the width of the p type deep layer 10 is changed between the heavily doped region 10a and the lightly doped region 10b, the opening width of a mask to be used for the formation of the n⁻ type drift layer should also he changed. In addition, as in the sixth embodiment, the width of the p type deep layer 10 is reduced with a decrease in the depth of the p type deep layer 10, the opening portion of a mask to be used for the formation of the it type drift layer 2 is tapered by using, for example, isotropic etching. Moreover, as in the seventh embodiment, a portion of the n⁻ type drift layer 2 is remained on the side surface of the trench 6, n type impurities may be implanted into this portion,

### Tenth Embodiment

A tenth embodiment will next be described. In this embodiment, a manufacturing method of the SIC semiconductor device having the structure of the eighth embodiment, which method is different from that employed in the eighth embodiment, will be described.

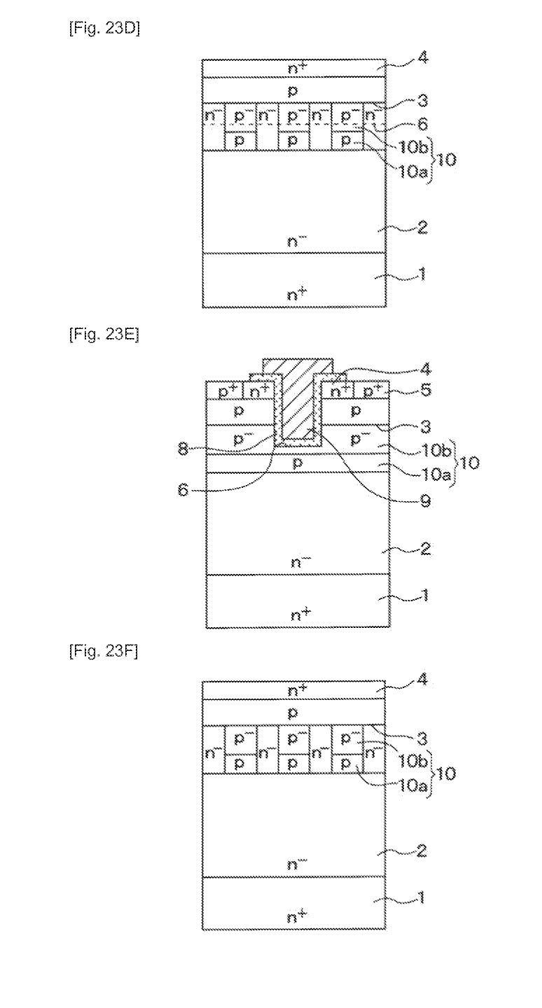

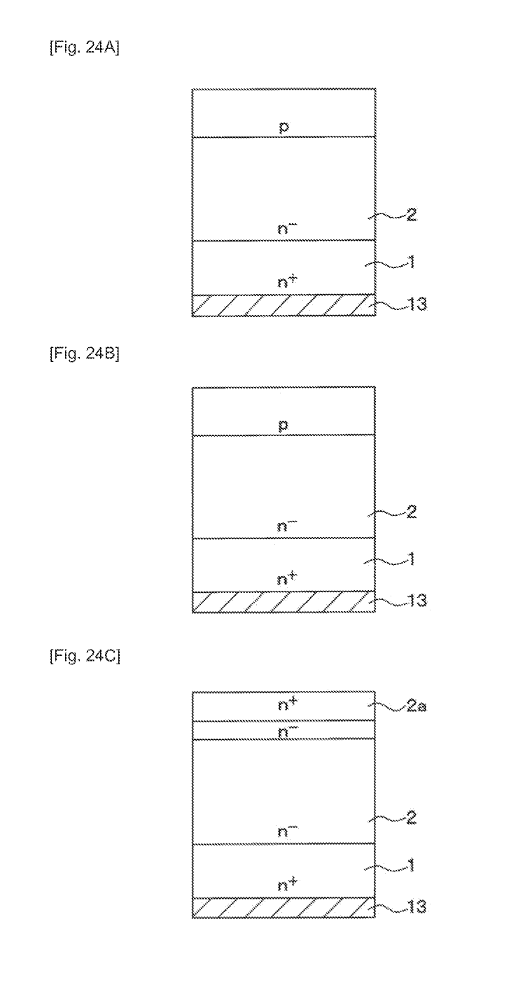

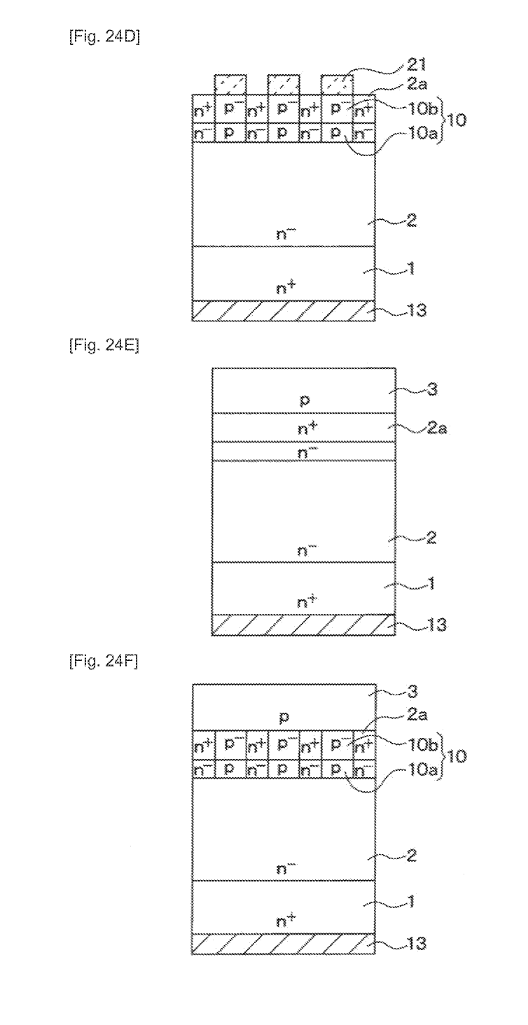

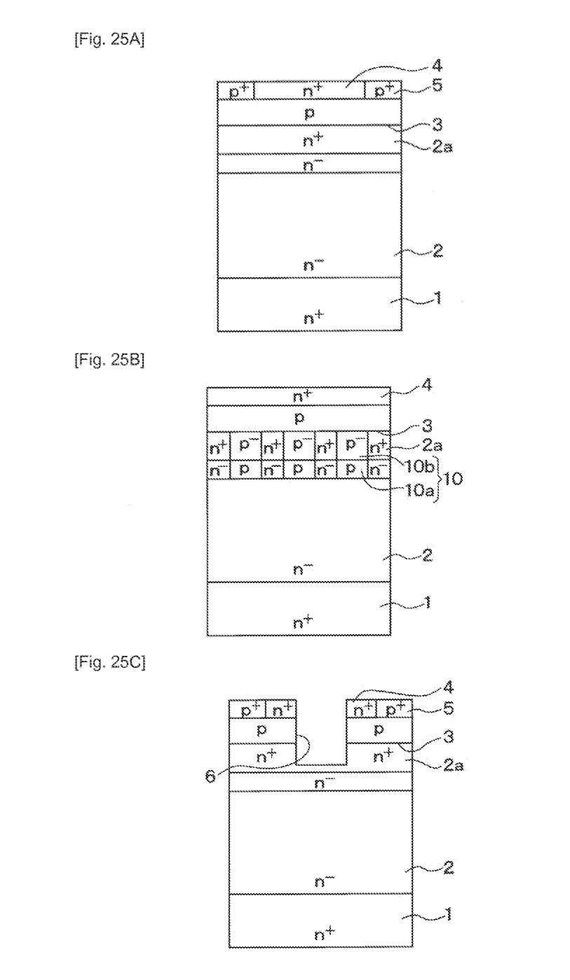

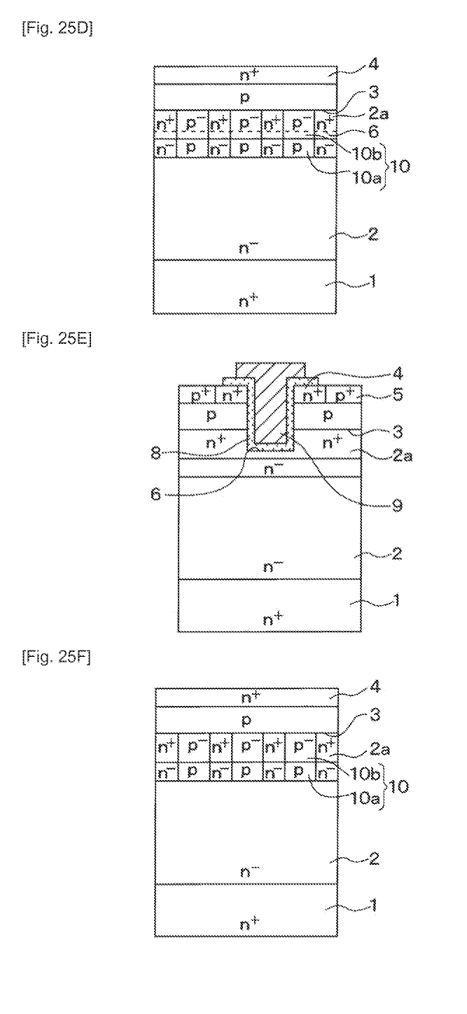

FIGS. 24A to 24F and FIGS. 25A to 25F are cross-sectional views showing manufacturing steps of the SiC semiconductor device of the present embodiment. In FIGS. 24A to 24F and FIGS. 25A to 25F, a cross-sectional view (area corresponding to FIG. 21A) taken along the line XXIA-XXIA in parallel with the xz plane in FIG. 20 is shown on the left side and a cross-sectional view (area corresponding to FIG. 21B) taken along the line XXIB-XXIB in parallel with the yz plane in FIG. 20 is shown on the right side. The manufacturing method of the SiC semiconductor device according to the present embodiment will be described referring to these drawings.

In the step shown in FIGS. 24A and 24B, after formation of an w type drift layer 2 by epitaxial growth on the surface of the n⁺ type substrate 1, a heavily doped region 10a of the p type deep layer 10 having a thickness corresponding to the thickness of the entirety of the p type deep layer 10 is formed by epitaxial growth on the surface of the n⁻ type drift layer 2. Then, in the step shown in FIGS. 24C and 24D, n type impurities (such as nitrogen) are implanted to reduce the carrier concentration of the upper layer portion of the p type deep layer 10, thereby forming a lightly doped region 10b. Further, a mask 21 is placed and n type impurities (such as nitrogen) are implanted therethrough to partially invert the p type deep layer 10 to n type SiC, thereby forming a region of the n− type drift layer 2 sandwiched between two adjacent p type deep layers 10 and at the same time, forming a current diffusion layer 2a. At this time, since ion implantation enough for inverting the heavily doped region 10a to n type one is performed, the current diffusion layer 2a has a higher n type impurity concentration than the n⁻ type drift layer 2.

Then, by carrying out, as the steps shown in FIGS. 24E and 24F and FIGS. 25A to 25F, steps similar to those shown in FIGS. 4E and 4F and FIGS. 5A to 5F described in the first embodiment, a SiC semiconductor device having a structure similar to that of the eighth embodiment can be manufactured,

Thus, it is possible to form a region of the n⁻ type drift layer 2 sandwiched between two adjacent p type deep layers 10 or the current diffusion layer 2a after formation of the p type deep layer 10. According to such a manufacturing method, the p type deep layer 10 can be formed not by ion implantation but epitaxial growth so that the heavily doped region 10a can be formed as a region having a higher concentration or a region of the n⁻ type drift layer ‘2 sandwiched between two adjacent p type deep layers 10 can be formed as a region having a higher concentration than a region positioned below the p type deep layer 10. Alternatively, it becomes possible to automatically form a concentration gradient so as to form the current diffusion layer 2a having a higher concentration.

### Another Embodiment

In the above first and second embodiments, the p type deep layer 10 is extended in a x direction, but each p type deep layer 10 may be obliquely crossed with the longitudinal direction of the trench 6 or may be divided into two or more portions in the x direction. When the p type deep layer 10 is obliquely crossed with the longitudinal direction of the trench 6, it is preferred, in order to prevent an uneven equipotential distribution, to arrange the p type deep layer 10 in line symmetry, with a line extending in a direction perpendicular to the longitudinal direction of the trench 6 as a symmetry line.

In the above embodiments, the description is made with, as an example, an n channel type MOSFET having an n type as the first conductivity type and a p type as the second conductivity type. The disclosure can also be applied to a p channel type MOSFET in which the conductivity type of each of the constituting elements have been reversed. In addition, in the above description, a MOSFET having a trench gate structure is used. The disclosure can also be applied to an IGBT having a similar trench gate structure. The structure or the manufacturing method of the IGBT is similar to that of the above embodiments except that the conductivity type of the substrate t is changed from n type to p type.

In the above embodiments, the gate oxide film $ made by thermal oxidation is used as an example of a gate insulating film. The gate insulating film is not limited thereto but it may include an oxide film not formed by thermal oxidation or a nitride film.

The above disclosure has the following aspects.

According to a first aspect of the present disclosure, a silicon carbide semiconductor device includes: an inversion type MOSFET with a trench gate structure. The inversion type MOSFET includes: a substrate having first or second conductivity type and made of silicon carbide; a drift layer disposed on the substrate, having an impurity concentration lower than the substrate, having the first conductivity type, and made of silicon carbide; a base region disposed on the drift layer, having the second conductivity type, and made of silicon carbide; a source region disposed in an upper portion of the base region, having an impurity concentration higher than the drift layer, having the first conductivity type, and made of silicon carbide; a contact region disposed in another upper portion of the base region, having an impurity concentration higher than the base layer, having the second conductivity type, and made of silicon carbide; a trench extending from a surface of the source region to penetrate the base region, and having a first direction as a longitudinal direction; a gate insulating film disposed on an inner wall of the trench; a gate electrode disposed on the gate insulating film in the trench; a source electrode electrically coupled with the source region and electrically coupled with the base region via the contact region; and a drain electrode disposed on a back side of the substrate. The inversion type MOSFET is configured to flow current between the source electrode and the drain electrode via the source region, an inversion type channel region and the drift layer. The inversion type channel region is provided in a portion of the base region positioned on a side of the trench by controlling a gate voltage applied to the gate electrode. The inversion type MOSFET further includes: a plurality of deep layers having the second conductivity type. Each deep layer is disposed in an upper portion of the drift layer below the base region, has a depth deeper than the trench, and extends along a second direction, which crosses the first direction. Each deep layer has an impurity concentration distribution in a depth direction of the deep layer. When the gate voltage is applied to the gate electrode, an inversion layer is provided in a portion of the deep layer positioned on the side of the trench.

In the above device, since the current flowing through the channel flows not only the channel but also the inversion layer formed in the portion of the deep layer. Thus, a JFET region between the deep layers has a low JFET resistance, so that an on-state resistance is reduced.

Alternatively, the impurity concentration distribution of each deep layer may be a stepwise concentration gradient in the depth direction of the deep layer. Further, each deep layer may include a heavily doped region having the second conductivity type and a lightly doped region having the second conductivity typo. An impurity concentration of the heavily doped region is higher than the lightly doped region. The lightly doped region is located on the side of the trench. When the gate voltage is applied to the gate electrode, a portion of the lightly doped region located on the side of the trench provides the inversion layer. Furthermore, a boundary between the heavily doped region and the lightly doped region may be deeper than the trench. In these cases, the lightly doped region positioned under the bottom of the trench in addition to the side of the trench provides the inversion layer. Thus, since the current flows under the bottom of the trench, the JFET resistance is much reduced, and therefore, the on-state resistance is reduced.

Alternatively, the impurity concentration distribution of each deep layer may be a concentration gradient, in which the impurity concentration decreases as the depth of the deep layer is made shallow.

Alternatively, a width of each deep layer may decrease as the depth of the deep layer is lade shallow. In this case, since the width of the drift layer adjacent to a shallow portion of the deep layer becomes wide, the current path is made wider even in a region, which does not form the inversion layer when the gate voltage is applied to the gate electrode. Thus, the JFET region between the deep layers has the low JFET resistance, so that an on-state resistance is reduced.

Alternatively, the inversion type MOSFET may further include: a first conductivity type layer on the side of the trench. Each deep layer is located below the first conductivity layer. In this case, when the MOSFET turns on, the current flows through the first conductivity type layer on the side of the trench. Further, the inversion layer is formed on the side of the trench partially. Thus, the JFET region between the deep layers has the low JFET resistance, so that an on-state resistance is reduced.

Alternatively, the inversion type MOSFET may further include: a current diffusion layer having the first conductivity type. The current diffusion layer is disposed in the drift layer between the plurality of deep layers, and the current diffusion layer has an impurity concentration higher than the drift layer, which is located below the deeper layer. In this case, the range in which the current flows becomes wide in the current diffusion layer having the low resistance. Thus, the current also flows in a portion spaced apart from the trench gate structure, and therefore, the on-state resistance is much reduced.

According to a second aspect of the present disclosure, a method of manufacturing a silicon carbide semiconductor device includes: forming a drift layer on a substrate, wherein the substrate is made of silicon carbide and has a first or second conductivity type, and the drift layer is made of silicon carbide, has the first conductivity type, and has an impurity concentration lower than the substrate; forming a plurality of deep layers having the second conductivity type in a surface portion of the drift layer by implanting an ion on a surface of the drift layer through a first mask after the first mask is formed on the surface of the drift layer; forming a base region having the second conductivity type and made of silicon carbide on the deep layers and the drift layer; forming a source region in a surface portion of the base region by implanting a first conductivity type impurity on a surface of the base region, wherein the source region has an impurity concentration higher than the drift layer, having the first conductivity type, and made of silicon carbide; forming a contact region in another surface portion of the base region by implanting a second conductivity type impurity on the surface of the base region, wherein the contact region has an impurity concentration higher than the base region, having the second conductivity type, and made of silicon carbide; forming a trench on a surface of the source region to penetrate the base region and to reach the drift layer, wherein the trench is shallower than each deep layer, and has a first direction as a longitudinal direction; forming a gate insulating film on an inner wall of the trench; forming a gate electrode on the gate insulating film in the trench; forming a source electrode to be electrically coupled with the source region and to be coupled with the base region via the contact region; and forming a drain electrode on a back side of the substrate. Each deep layer is disposed in an upper portion of the drift layer below the base region, has a depth deeper than the trench, and extends along a second direction, which crosses the first direction. Each deep layer has an impurity concentration distribution in a depth direction of the deep layer. When the gate voltage is applied to the gate electrode, an inversion layer is provided in a portion of the deep layer positioned on the side of the trench.

In the above method, since the current flowing through the channel flows not only the channel but also the inversion layer formed in the portion of the deep layer. Thus, a JFET region between the deep layers has a low JFET resistance, so that an on-state resistance is reduced.

According to a third aspect of the present disclosure, a method of manufacturing a silicon carbide semiconductor device includes: forming a drift layer on a substrate, wherein the substrate is made of silicon carbide and has a first or second conductivity type, and the drift layer is made of silicon carbide, has the first conductivity type, and has an impurity concentration lower than the substrate; forming a second conductivity type film on a surface of the drift layer by an epitaxial growth method; implanting an ion on a surface of the second conductivity type film through a first mask after the first mask is formed on the surface of the second conductivity type film so that the second conductivity type film is divided into a plurality of parts, each of which provide a corresponding deep layer, and an implanted part of the second conductivity type film between a plurality of deep layers provides the drift layer; forming a base region having the second conductivity type and made of silicon carbide on the deep layers and the drift layer; forming a source region in a surface portion of the base region by implanting a first conductivity type impurity on a surface of the base region, wherein the source region has an impurity concentration higher than the drift layer, having the first conductivity type, and made of silicon carbide; forming a contact region in another surface portion of the base region by implanting a second conductivity type impurity on the surface of the base region, wherein the contact region has an impurity concentration higher than the base region, having the second conductivity type, and made of silicon carbide; forming a trench on a surface of the source region to penetrate the base region and to reach the drift layer, wherein the trench is shallower than each deep layer, and has a first direction as a longitudinal direction; forming a gate insulating film on an inner wall of the trench; forming a gate electrode on the gate insulating film in the trench; forming a source electrode to be electrically coupled with the source region and to be coupled with the base region via the contact region; and forming a drain electrode on a back side of the substrate. Each deep layer is disposed in an upper portion of the drift layer below the base region, has a depth deeper than the trench, and extends along a second direction, which crosses the first direction. Each deep layer has an impurity concentration distribution in a depth direction of the deep layer. When the gate voltage is applied to the gate electrode, an inversion layer is provided in a portion of the deep layer positioned on the side of the trench.

In the above method, since the current flowing through the channel flows not only the channel but also the inversion layer formed in the portion of the deep layer. Thus, a JFET region between the deep layers has a low JFET resistance, so that an on-state resistance is reduced.

Alternatively, the implanting of the ion on the surface of the second conductivity type film through the first mask may include: implanting a first conductivity type impurity on the surface of the second conductivity type film so that a carrier concentration of an upper portion of the second conductivity type film is reduced; forming the first mask on the surface of the second conductivity type film; and implanting the ion on the surface of the second conductivity type film through the first mask after the first mask is formed on the surface of the second conductivity type film so that the second conductivity type film is divided into the plurality of parts, each of which provide a corresponding deep layer, the implanted part of the upper portion of the second conductivity type film between a plurality of deep layers provides a current diffusion layer, and the implanted part of a lower portion of the second conductivity type film between a plurality of deep layers provides the drift layer. The current diffusion layer has the first conductivity type, and has an impurity concentration higher than the drift layer. In this case, when the drift layer is formed between the deep layers, the current diffusion layer is also formed in the upper portion of the second conductivity type film. Thus, the impurity concentration in the upper and the lower portions of the second conductivity type film is automatically controlled to have a certain concentration gradient such that the impurity concentration of the current diffusion layer is high.

While the disclosure has been described with reference to preferred embodiments thereof, it is to be understood that the disclosure is not limited to the preferred embodiments and constructions. The disclosure is intended to cover various modification and equivalent arrangements. In addition, while the various combinations and configurations, which are preferred, other combinations and configurations, including more, less or only a single element, are also within the spirit and scope of the disclosure.

1. A silicon carbide semiconductor device comprising:
an inversion type MOSFET with a trench gate structure,
wherein the inversion type MOSFET includes:
a substrate having first or second conductivity type and made of silicon carbide;
a drift layer disposed on the substrate, having an impurity concentration lower than the substrate, having the first conductivity type, and made of silicon carbide;
a base region disposed on the drift layer, having the second conductivity type, and made of silicon carbide;
a source region disposed in an upper portion of the base region, having an impurity concentration higher than the drift layer, having the first conductivity type, and made of silicon carbide;
a contact region disposed in another upper portion of the base region, having an impurity concentration higher than the base layer, having the second conductivity type, and made of silicon carbide;
a trench extending from a surface of the source region to penetrate the base region, and having a first direction as a longitudinal direction;
a gate insulating film disposed on an inner wall of the trench;
a gate electrode disposed on the gate insulating film in the trench;
a source electrode electrically coupled with the source region and electrically coupled with the base region via the contact region; and
a drain electrode disposed on a back side of the substrate,
wherein the inversion type MOSFET is configured to flow current between the source electrode and the drain electrode via the source region, an inversion type channel region and the drift layer,
wherein the inversion type channel region is provided in a portion of the base region positioned on a side of the trench by controlling a gate voltage applied to the gate electrode,
wherein the inversion type MOSFET further includes: a plurality of deep layers having the second conductivity type,
wherein each deep layer is disposed in an upper portion of the drift layer below the base region, has a depth deeper than the trench, and extends along a second direction, which crosses the first direction,
wherein each deep layer has an impurity concentration distribution in a depth direction of the deep layer, and
wherein, when the gate voltage is applied to the gate electrode, an inversion layer is provided in a portion of the deep layer positioned on the side of the trench.

2. The silicon carbide semiconductor device according to claim 1,
wherein the impurity concentration distribution of each deep layer is a stepwise concentration gradient in the depth direction of the deep layer.

3. The silicon carbide semiconductor device according to claim 1,
wherein each deep layer includes a heavily doped region having the second conductivity type and a lightly doped region having the second conductivity type,
wherein an impurity concentration of the heavily doped region is higher than the lightly doped region,
wherein the lightly doped region is located on the side of the trench, and
wherein, when the gate voltage is applied to the gate electrode, a portion of the lightly doped region located on the side of the trench provides the inversion layer.

4. The silicon carbide semiconductor device according to claim 3,
wherein a boundary between the heavily doped region and the lightly doped region is deeper than the trench.

5. The silicon carbide semiconductor device according to claim 1,
wherein the impurity concentration distribution of each deep layer is a concentration gradient, in which the impurity concentration decreases as the depth of the deep layer is made shallow.

6. The silicon carbide semiconductor device according to claim 1,
wherein a width of each deep layer decreases as the depth of the deep layer is made shallow.

7. The silicon carbide semiconductor device according to claim 1,
wherein the inversion type MOSFET further includes: a first conductivity type layer on the side of the trench,
wherein each deep layers is located below the first conductivity layer.

8. The silicon carbide semiconductor device according to claim 1,
wherein the inversion type MOSFET further includes: a current diffusion layer having the first conductivity type,
wherein the current diffusion layer is disposed in the drift layer between the plurality of deep layers, and
wherein the current diffusion layer has an impurity concentration higher than the drift layer, which is located below the deeper layer.

9. A method of manufacturing a silicon carbide semiconductor device comprising:
forming a drift layer on a substrate, wherein the substrate is made of silicon carbide and has a first or second conductivity type, and the drift layer is made of silicon carbide, has the first conductivity type, and has an impurity concentration lower than the substrate;
forming a plurality of deep layers having the second conductivity type in a surface portion of the drift layer by implanting an ion on a surface of the drift layer through a first mask after the first mask is formed on the surface of the drift layer;
forming a base region having the second conductivity type and made of silicon carbide on the deep layers and the drift layer;
forming a source region in a surface portion of the base region by implanting a first conductivity type impurity on a surface of the base region, wherein the source region has an impurity concentration higher than the drift layer, having the first conductivity type, and made of silicon carbide;
forming a contact region in another surface portion of the base region by implanting a second conductivity type impurity on the surface of the base region, wherein the contact region has an impurity concentration higher than the base region, having the second conductivity type, and made of silicon carbide;
forming a trench on a surface of the source region to penetrate the base region and to reach the drift layer, wherein the trench is shallower than each deep layer, and has a first direction as a longitudinal direction;
forming a gate insulating film on an inner wall of the trench;
forming a gate electrode on the gate insulating film in the trench;
forming a source electrode to be electrically coupled with the source region and to be coupled with the base region via the contact region; and
forming a drain electrode on a back side of the substrate,
wherein each deep layer is disposed in an upper portion of the drift layer below the base region, has a depth deeper than the trench, and extends along a second direction, which crosses the first direction,
wherein each deep layer has an impurity concentration distribution in a depth direction of the deep layer, and
wherein, when the gate voltage is applied to the gate electrode, an inversion layer is provided in a portion of the deep layer positioned on the side of the trench.

10. A method of manufacturing a silicon carbide semiconductor device comprising:
forming a drift layer on a substrate, wherein the substrate is made of silicon carbide and has a first or second conductivity type, and the drift layer is made of silicon carbide, has the first conductivity type, and has an impurity concentration lower than the substrate;
forming a second conductivity type film on a surface of the drift layer by an epitaxial growth method;
implanting an ion on a surface of the second conductivity type film through a first mask after the first mask is formed on the surface of the second conductivity type film so that the second conductivity type film is divided into a plurality of parts, each of which provide a corresponding deep layer, and an implanted part of the second conductivity type film between a plurality of deep layers provides the drift layer;
forming a base region having the second conductivity type and made of silicon carbide on the deep layers and the drift layer;
forming a source region in a surface portion of the base region by implanting a first conductivity type impurity on a surface of the base region, wherein the source region has an impurity concentration higher than the drift layer, having the first conductivity type, and made of silicon carbide;
forming a contact region in another surface portion of the base region by implanting a second conductivity type impurity on the surface of the base region, wherein the contact region has an impurity concentration higher than the base region, having the second conductivity type, and made of silicon carbide;
forming a trench on a surface of the source region to penetrate the base region and to reach the drift layer, wherein the trench is shallower than each deep layer, and has a first direction as a longitudinal direction;
forming a gate insulating film on an inner wall of the trench;
forming a gate electrode on the gate insulating film in the trench;
forming a source electrode to be electrically coupled with the source region and to be coupled with the base region via the contact region; and
forming a drain electrode on a back side of the substrate,
wherein each deep layer is disposed in an upper portion of the drift layer below the base region, has a depth deeper than the trench, and extends along a second direction, which crosses the first direction,
wherein each deep layer has an impurity concentration distribution in a depth direction of the deep layer, and
wherein, when the gate voltage is applied to the gate electrode, an inversion layer is provided in a portion of the deep layer positioned on the side of the trench.

11. The method of manufacturing a semiconductor device according to claim 10,
wherein the implanting of the ion on the surface of the second conductivity type film through the first mask includes:
implanting a first conductivity type impurity on the surface of the second conductivity type film so that a carrier concentration of an upper portion of the second conductivity type film is reduced;
forming the first mask on the surface of the second conductivity type film; and
implanting the ion on the surface of the second conductivity type film through the first mask after the first mask is formed on the surface of the second conductivity type film so that the second conductivity type film is divided into the plurality of parts, each of which provide a corresponding deep layer, the implanted part of the upper portion of the second conductivity type film between a plurality of deep layers provides a current diffusion layer, and the implanted part of a lower portion of the second conductivity type film between a plurality of deep layers provides the drift layer, and
wherein the current diffusion layer has the first conductivity type, and has an impurity concentration higher than the drift layer.
